(19) United States
(12) Patent Application Publication
(10) Pub. No.: US 2024/0063002 A1
(43) Pub. Date: Feb. 22, 2024

(54) PLASMA PROCESSING APPARATUS AND METHOD FOR DETECTING END POINT

(71) Applicant: Tokyo Electron Limited, Tokyo (JP)

(72) Inventor: Masakazu HAYASHI, Miyagi (JP)

(73) Assignee: Tokyo Electron Limited, Tokyo (JP)

(21) Appl. No.: 18/501,056

(22) Filed: Nov. 3, 2023

Related U.S. Application Data
(63) Continuation of application No. PCT/JP2022/019422, filed on Apr. 28, 2022.

(30) Foreign Application Priority Data
May 6, 2021 (JP) 2021-078326
Sep. 29, 2021 (JP) 2021-158816

(51) Int. Cl. H01J 37/32

(52) U.S. Cl. CPC H01J 37/32963; H01J 37/32091; H01J 37/32862; H01J 2237/24564; H01J 2237/334

(57) ABSTRACT

A measuring unit is provided in an electrode disposed inside a chamber or a wire connected to the electrode and measures either a voltage or a current. A gas supply unit supplies a gas to be made into plasma into the chamber. A radio-frequency power supply supplies radio-frequency power in a pulse form making the gas supplied into the chamber plasma to the chamber. A detector detects an end point of plasma processing from a change in any of a voltage, a current, and a phase difference between the voltage and the current measured by the measuring unit with a timing synchronized with a cycle of pulses of the radio-frequency power.

### CROSS-REFERENCE TO RELATED APPLICATIONS

This application is a continuation of International Application No. PCT/JP2022/019422, filed on Apr. 28, 2022 which claims the benefit of priority of the prior Japanese Patent Application No. 2021-078326, filed on May 6, 2021 and Japanese Patent Application No. 2021-158816, filed on Sep. 29, 2021, the entire contents of each are incorporated herein by reference.

### FIELD

The present disclosure relates to a plasma processing apparatus and a method for detecting an end point.

### BACKGROUND

U.S. Patent Application Publication No. 2005/0217795 discloses a technique for detecting an end point of etching from a signal measured by a VI probe during plasma etching.

The present disclosure provides a technique for accurately detecting an end point of plasma processing.

### SUMMARY

According to an aspect of a present disclosure, a plasma processing apparatus includes a chamber, a chamber provided inside with a placing pedestal on which a substrate is placed; an electrode disposed inside the chamber; a measuring unit provided in the electrode or a wire connected to the electrode and configured to measure either a voltage or a current; a gas supply unit configured to supply a gas to be made into plasma into the chamber; a radio-frequency power supply configured to supply, to the chamber, radio-frequency power in a pulse form making the gas supplied into the chamber plasma; and a detector configured to detect an end point of plasma processing by the plasma generated inside the chamber from a change in any of a voltage, a current, and a phase difference between the voltage and the current measured by the measuring unit with a timing synchronized with a cycle of pulses of the radio-frequency power.

### BRIEF DESCRIPTION OF DRAWINGS

FIG. 1 is a diagram of an example of a schematic configuration of a plasma processing apparatus according to a first embodiment.

FIG. 2 is a block diagram of an example of a schematic configuration of a controller according to the first embodiment.

FIG. 3 is a diagram illustrating detection of an end point of etching according to the first embodiment.

FIG. 4 is a diagram illustrating conventional detection of an end point of etching.

FIG. 5 is a diagram of an example of a substrate to be etched according to the first embodiment.

FIG. 6 is a diagram illustrating detection of the end point of the etching according to the first embodiment.

FIG. 7 is a diagram illustrating an example of detection of the end of the etching according to the first embodiment.

FIG. 8A is a diagram of an example of the substrate according to the first embodiment.

FIG. 8B is a diagram of an example of the substrate according to the first embodiment.

FIG. 9 is a diagram illustrating an example of a measurement result by a measuring unit according to the first embodiment.

FIG. 10 is a diagram illustrating an example of a measurement result by an OES according to a comparative example.

FIG. 11A is a diagram of an example of a source RF signal, a bias RF signal, and a period of detecting the end point of the etching according to the first embodiment.

FIG. 11B is a diagram of an example of the source RF signal, the bias RF signal, and the period of detecting the end point of the etching according to the first embodiment.

FIG. 11C is a diagram of an example of the source RF signal, the bias RF signal, and the period of detecting the end point of the etching according to the first embodiment.

FIG. 11D is a diagram of an example of the source RF signal, the bias RF signal, and the period of detecting the end point of the etching according to the first embodiment.

FIG. 11E is a diagram of an example of the source RF signal, the bias RF signal, and the period of detecting the end point of the etching according to the first embodiment.

FIG. 12 is a diagram illustrating an example of a processing procedure of a method for detecting an end point according to the first embodiment.

FIG. 13 is a diagram of an example of a schematic configuration of the plasma processing apparatus according to a second embodiment.

FIG. 14 is a block diagram of an example of a schematic configuration of the controller according to the second embodiment.

FIG. 15 is a diagram of an example of supply of radio-frequency power according to the second embodiment.

FIG. 16 is a diagram illustrating detection of an end point of cleaning according to the second embodiment.

FIG. 17 is a diagram illustrating a procedure of the cleaning according to the second embodiment.

FIG. 18 is a diagram illustrating an example of a procedure detecting the end point of the cleaning according to the second embodiment.

FIG. 19 is a diagram illustrating an example of a processing procedure of a method for detecting an end point according to the second embodiment.

FIG. 20 is a diagram of another example of supply of the radio-frequency power according to the second embodiment.

FIG. 21 is a diagram of another example of supply of the radio-frequency power according to the second embodiment.

FIG. 22 is a diagram schematically illustrating an example of supply routes for RF signals in the plasma processing apparatus according to the second embodiment.

FIG. 23 is a diagram schematically illustrating another example of the supply routes for the RF signals in the plasma processing apparatus according to the second embodiment.

FIG. 24 is a diagram schematically illustrating another example of the supply routes for the RF signals in the plasma processing apparatus according to the second embodiment.

FIG. 25 is a diagram schematically illustrating another example of the supply routes for the RF signals in the plasma processing apparatus according to the second embodiment.

### DESCRIPTION OF EMBODIMENTS

The following describes embodiments of a plasma processing apparatus and a method for detecting an end point disclosed by the present application in detail with reference to the accompanying drawings. The present embodiments do not limit the plasma processing apparatus and the method for detecting an end point disclosed.

In plasma etching, used is a method of detecting an end point of etching in real time and stopping an etching process in order to prevent excessive etching and reduce variations in pattern shape. Examples of conventional methods for detecting an end point of etching include a method of detecting an end point of etching from a change in the emission intensity of plasma during etching using an optical emission sensor (OES). There is also a method for detecting an end point of etching from a signal measured by a VI probe during plasma etching.

By the way, cycle etching, in which radio-frequency (RF) power is applied repeatedly in a pulse form, is more effective in improving processing accuracy than conventional etching, in which RF power of constant power is applied over time. The cycle etching is becoming mainstream etching, including processes with strict processing accuracy. However, conventional methods for detecting an end point of etching cannot accurately detect an end point of etching. Given these circumstances, a technology to accurately detect an end point of etching is expected.

In the plasma processing apparatus, cleaning is performed to remove a deposition adhering inside a plasma processing chamber using plasma. For such cleaning also, the method of repeatedly applying RF power in a pulse form is effective in removing the deposition. For the cleaning also, to prevent excessive etching inside the plasma processing chamber by plasma, a technique to accurately detect an end point of the cleaning is expected.

Thus, a technique to accurately detect the end point of plasma processing such as etching and cleaning is expected.

### First Embodiment

Apparatus Configuration

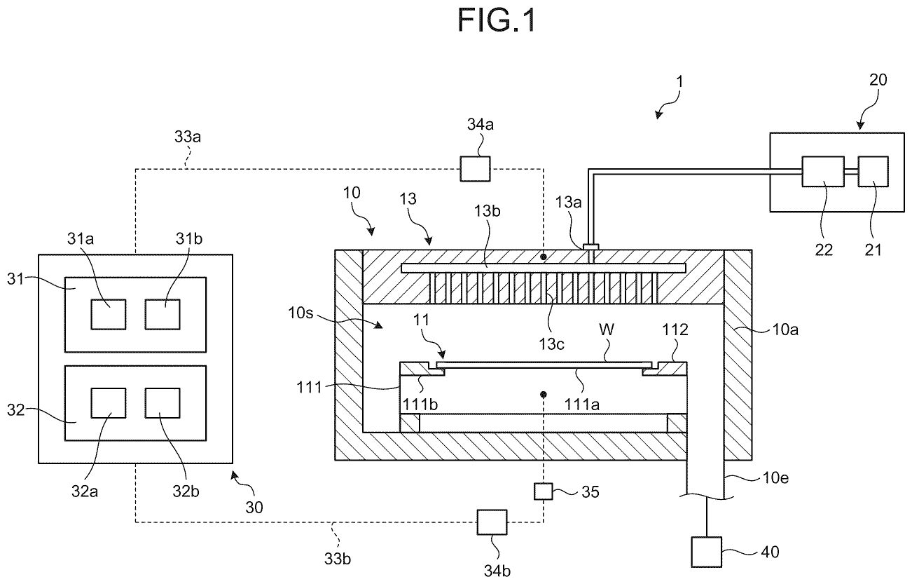

The first embodiment describes a case in which the end point of the plasma processing etching a substrate is detected. The following describes an example of a plasma processing apparatus according to the present disclosure. FIG. 1 is a diagram of an example of a schematic configuration of a plasma processing apparatus 1 according to the first embodiment.

The following describes a configuration example of a capacitive coupling plasma processing apparatus as an example of the plasma processing apparatus 1. The capacitive coupling plasma processing apparatus 1 includes a plasma processing chamber 10, a gas supply unit 20, a power supply 30, and an exhaust system 40. The plasma processing apparatus 1 also includes a substrate support 11 and a gas introduction unit. The gas introduction unit is configured to introduce at least one processing gas into the plasma processing chamber 10. The gas introduction unit includes a shower head 13. The substrate support 11 is disposed inside the plasma processing chamber 10. The shower head 13 is disposed above the substrate support 11. In one embodiment, the shower head 13 forms at least part of a ceiling of the plasma processing chamber 10. The plasma processing chamber 10 has a plasma processing space 10s defined by the shower head 13, a side wall 10a of the plasma processing chamber 10, and the substrate support 11. The side wall 10a is grounded. The shower head 13 and the substrate support 11 are electrically isolated from the plasma processing chamber 10 housing.

The substrate support 11 includes a main body 111 and a ring assembly 112. The main body 111 has a central area (a substrate support face) 111a for supporting a substrate (wafer) W and an annular area (a ring support face) 111b for supporting the ring assembly 112. The annular area 111b of the main body 111 surrounds the central area 111a of the main body 111 in a plan view. The substrate W is disposed on the central area 111a of the main body 111, while the ring assembly 112 is disposed on the annular area 111b of the main body 111 so as to surround the substrate W on the central area 111a of the main body 111. In one embodiment, the main body 111 includes a base and an electrostatic chuck. The base includes a conductive member. The conductive member of the base functions as a lower electrode. The electrostatic chuck is disposed above the base. The upper surface of the electrostatic chuck has the substrate support face 111a. The ring assembly 112 includes one or a plurality of annular members. At least one of the one or more annular members is an edge ring. Although not illustrated, the substrate support 11 may include a temperature adjusting module configured to adjust at least one of the electrostatic chuck, the ring assembly 112, and the substrate to a target temperature. The temperature adjusting module may include a heater, a heat conductive medium, a flow channel, or a combination of these. Through the flow channel, a heat conductive fluid such as brine or gas flows. The substrate support 11 may include a heat conductive gas supply unit configured to supply a heat conductive gas to between the back face of the substrate W and the substrate support face 111a.

The shower head 13 is configured to introduce the at least one processing gas from the gas supply unit 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b to be introduced into the plasma processing space 10s through the gas introduction ports 13c. The shower head 13 includes a conductive member. The conductive member of the shower head 13 functions as an upper electrode. In addition to the shower head 13, the gas introduction unit may include one or a plurality of side gas injectors (SGIs) mounted on one or a plurality of openings formed in the side wall 10a.

The gas supply unit 20 may include at least one gas source 21 and at least one flow controller 22. In one embodiment, the gas supply unit 20 is configured to supply the at least one processing gas to the shower head 13 from the gas source 21 corresponding to each gas via the flow controller 22 corresponding to each gas. Each flow controller 22 may include, for example, a mass flow controller or a pressure-controlled flow controller. Further, the gas supply unit 20 may include at least one flow modulating device modulating or pulsing the flow of the at least one processing gas.

The power supply 30 includes an RF power supply 31 coupled to the plasma processing chamber 10 via at least one impedance matching circuit. The RF power supply 31 is configured to supply at least one RF signal (RF power) such as a source RF signal or a bias RF signal to the conductive member of the substrate support 11 and/or the conductive member of the shower head 13. With this configuration, plasma is formed from the at least one processing gas supplied to the plasma processing space 10s. Thus, the RF power supply 31 can function as at least part of a plasma generation unit 12. By supplying the bias RF signal to the conductive member of the substrate support 11, a bias potential is generated in the substrate W, and an ion component in the formed plasma can be drawn to the substrate W.

In one embodiment, the RF power supply 31 includes a first RF generation unit 31a and a second RF generation unit 31b. The first RF generation unit 31a is coupled to the conductive member of the substrate support 11 and/or the conductive member of the shower head 13 via the at least one impedance matching circuit and is configured to generate the source RF signal (source RF power) for plasma generation. In one embodiment, the source RF signal has a frequency in a range of 13 MHz to 150 MHz. In one embodiment, the first RF generation unit 31a may be configured to generate a plurality of source RF signals having different frequencies. The generated one or more source RF signals are supplied to the conductive member of the substrate support 11 and/or the conductive member of the shower head 13. The second RF generation unit 31b is coupled to the conductive member of the substrate support 11 via the at least one impedance matching circuit and is configured to generate the bias RF signal (bias RF power). In one embodiment, the bias RF signal has the same frequency as that of the source RF signal or a frequency lower than that of the source RF signal. In one embodiment, the bias RF signal has a frequency in a range of 400 kHz to 50 MHz. In one embodiment, the second RF generation unit 31b may be configured to generate a plurality of bias RF signals having different frequencies. The generated one or more RF bias signals are supplied to the conductive member of the substrate support 11. In various embodiments, at least one of the source RF signal and the RF bias signal may be pulsed.

For example, the first RF generation unit 31a is electrically connected to the conductive member of the shower head 13 via a conductive part 33a such as a wire. The conductive part 33a is provided with an impedance matching circuit 34a. The impedance matching circuit 34a matches an output impedance of the first RF generation unit 31a and an input impedance of a load (the shower head 13) with each other. The first RF generation unit 31a supplies a first radio-frequency power with a first frequency for generating plasma to the conductive member of the shower head 13. For example, the first RF generation unit 31a supplies, as the first radio-frequency power, the source RF signal described above to the conductive member of the shower head 13 via the conductive part 33a and the impedance matching circuit 34a. The source RF signal is set to, for example, 60 MHz. The conductive member of the shower head 13 functions as an electrode. By the source RF signal being supplied, plasma with high density is generated inside the plasma processing chamber 10.

For example, the second RF generation unit 31b is electrically connected to the conductive member of the base of the substrate support 11 via a conductive part 33b such as a wire. The conductive part 33b is provided with an impedance matching circuit 34b. The impedance matching circuit 34b matches an output impedance of the second RF generation unit 31b and an input impedance of a load (the substrate support 11) with each other. The second RF generation unit 31b supplies, to the conductive member of the substrate support 11, a second radio-frequency power with a second frequency lower than the first frequency for drawing the ion component in the plasma to the substrate W. For example, the second RF generation unit 31b supplies, as the second radio-frequency power, the bias RF signal described above to the conductive member of the substrate support 11 via the conductive part 33b and the impedance matching circuit 34b. The bias RF signal is set to, for example, 40 MHz. The conductive member of the substrate support 11 functions as an electrode. By the bias RF signal being supplied, the ion component in the plasma generated inside the plasma processing chamber 10 is drawn to the substrate W.

The plasma processing apparatus 1 according to the present embodiment performs cycle etching and thus supplies, to the plasma processing chamber 10, the radio-frequency power in a pulse form from the RF power supply 31. For example, in the RF power supply 31, at least either the first RF generation unit 31a or the second RF generation unit 31b supplies the radio-frequency power in a pulse form.

The plasma processing apparatus 1 is provided with a measuring unit 35 measuring either a voltage or a current in the electrode disposed inside the plasma processing chamber 10 or the wire connected to the electrode. In the present embodiment, the measuring unit 35 is provided in the conductive part 33b connected to the conductive member of the substrate support 11. The measuring unit 35 includes a probe detecting the current or the voltage and measures the voltage or the current. The measuring unit 35 measures the voltage or the current of the conductive part 33b through which the bias RF signal passes and outputs a signal indicating the voltage or the current measured to a controller 100 described below.

The power supply 30 may include a DC power supply 32 coupled to the plasma processing chamber 10. The DC power supply 32 includes a first DC generation unit 32a and a second DC generation unit 32b. In one embodiment, the first DC generation unit 32a is connected to the conductive member of the substrate support 11 and is configured to generate a first DC signal. The generated first DC signal is applied to the conductive member of the substrate support 11. In one embodiment, the first DC signal may be applied to another electrode such as an electrode inside the electrostatic chuck. In one embodiment, the second DC generation unit 32b is connected to the conductive member of the shower head 13 and is configured to generate a second DC signal. The generated second DC signal is applied to the conductive member of the shower head 13. In various embodiments, the first and second DC signals may be pulsed. The first and second DC generation units 32a and 32b may be provided in addition to the RF power supply 31, or the first DC generation unit 32a may be provided instead of the second RF generation unit 31b.

The exhaust system 40 can be connected to, for example, a gas discharge port 10e provided at the bottom of the plasma processing chamber 10. The exhaust system 40 may include a pressure regulating valve or a vacuum pump. The pressure regulating valve regulates the pressure inside the plasma processing space 10s. The vacuum pump may include a turbo molecular pump, a dry pump, or a combination of these.

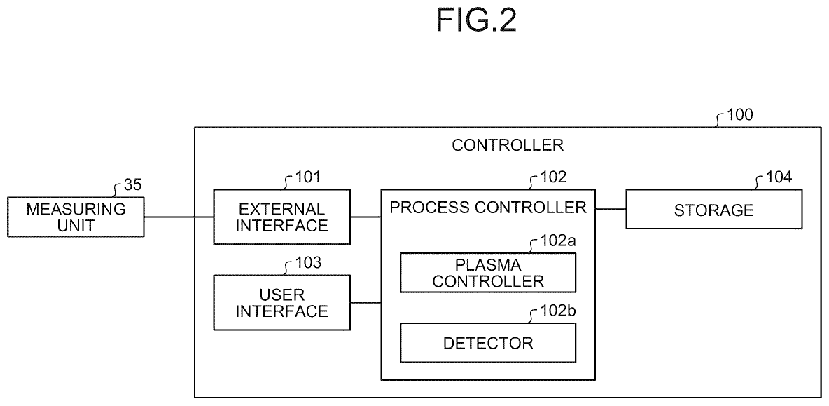

The plasma processing apparatus 1 configured as described above further includes the controller 100 described below. FIG. 2 is a block diagram of an example of a schematic configuration of the controller 100 according to the first embodiment. The controller 100 comprehensively controls the operation of the plasma processing apparatus 1 illustrated in FIG. 1.

The controller 100 is, for example, a computer and controls the parts of the plasma processing apparatus 1. The controller 100 comprehensively controls the operation of the plasma processing apparatus 1. The controller 100 performs control to cause the plasma processing apparatus 1 to execute various processes described in the present disclosure. The controller 100 is provided with an external interface 101, a process controller 102, a user interface 103, and a storage 104.

The external interface 101 is made communicable with the parts of the plasma processing apparatus 1 and receives input of and outputs various kinds of data. For example, the external interface 101 receives input of the signal indicating the voltage or the current measured by the measuring unit 35.

The process controller 102 includes a central processing unit (CPU) and controls the parts of the plasma processing apparatus 1.

The user interface 103 includes a keyboard allowing a process manager to perform command input operations in order to manage the plasma processing apparatus 1 and a display visualizing and displaying the operational status of the plasma processing apparatus 1.

The storage 104 stores therein a control program (software) for implementing various processes performed by the plasma processing apparatus 1 under the control of the process controller 102 and a recipe storing therein processing condition data and the like. As the control program and the recipe, ones stored in a computer-readable computer recording medium (for example, a hard disk, an optical disc such as a digital versatile disc (DVD), a flexible disk, a semiconductor memory, or the like) may be used. The control program and the recipe can also be transmitted from other devices at any time via, for example, a dedicated line to be used online.

The process controller 102 has an internal memory for storing therein computer programs and data, reads the control program stored in the storage 104, and executes the processing of the read control program. The process controller 102 functions as various processing units by the control program operating. For example, the process controller 102 has the functions of a plasma controller 102a and a detector 102b. The present embodiment describes a case as an example in which the process controller 102 has the functions of the plasma controller 102a and the detector 102b. However, the functions of the plasma controller 102a and the detector 102b may be implemented by being distributed among a plurality of controllers.

The plasma controller 102a controls the plasma processing. For example, the plasma controller 102a controls the exhaust system 40 to exhaust the inside of the plasma processing chamber 10 to a certain degree of vacuum. The plasma controller 102a controls the gas supply unit 20 to introduce the processing gas from the gas supply unit 20 into the plasma processing space 10s. The plasma controller 102a controls the power supply 30 to supply the source RF signal and the bias RF signal from the first RF generation unit 31a and the second RF generation unit 31b in sync with the introduction of the processing gas so as to generate plasma inside the plasma processing chamber 10.

The plasma processing apparatus 1 according to the present embodiment performs cycle etching. The plasma controller 102a controls the RF power supply 31 to supply the radio-frequency power from the RF power supply 31 in a pulse form. The RF power supply 31 supplies at least either the source RF signal or the bias RF signal in a pulse form. For example, the plasma controller 102a controls the RF power supply 31 to supply the source RF signal and the bias RF signal each in a pulse form from the first RF generation unit 31a and the second RF generation unit 31b. The frequency of the pulses turning on and off the supply of the source RF signal and the bias RF signal is set to 100 Hz to 10 kHz. In the following, out of the source RF signal and the bias RF signal, the source RF signal with a higher frequency is also referred to as high frequency (HF) and the bias RF signal with a lower frequency is also referred to as low frequency (LF).

The detector 102b detects the end point of the plasma processing from the voltage or the current of the signal input from the measuring unit 35. For example, the detector 102b detects the end point of the plasma processing from a change in any of a voltage, a current, and a phase difference between the voltage and the current measured by the measuring unit 35 with a timing synchronized with the cycle of the pulses of the radio-frequency power. In the present embodiment, the detector 102b detects an end point of etching from the change in any of the voltage, the current, and the phase difference between the voltage and the current measured by the measuring unit 35 with the timing synchronized with the cycle of the pulse of the radio-frequency power. The detector 102b detects the end point of the etching from the change in any of the voltage, the current, and the phase difference between the voltage and the current measured by the measuring unit 35 with a timing when a combination of the source RF signal and the bias RF signal supplied most contributes to the etching and a selection ratio. For example, in the present embodiment, the period during which the bias RF signal is supplied most contributes to the etching and the selection ratio. The detector 102b detects the end point of the etching from the change in any of the voltage, the current, and the phase difference between the voltage and the current measured by the measuring unit 35 in the period during which the bias RF signal is supplied.

The plasma controller 102a controls the plasma processing based on a detection result by the detector 102b. For example, the plasma controller 102a ends plasma etching upon detection of the end point of the etching by the detector 102b.

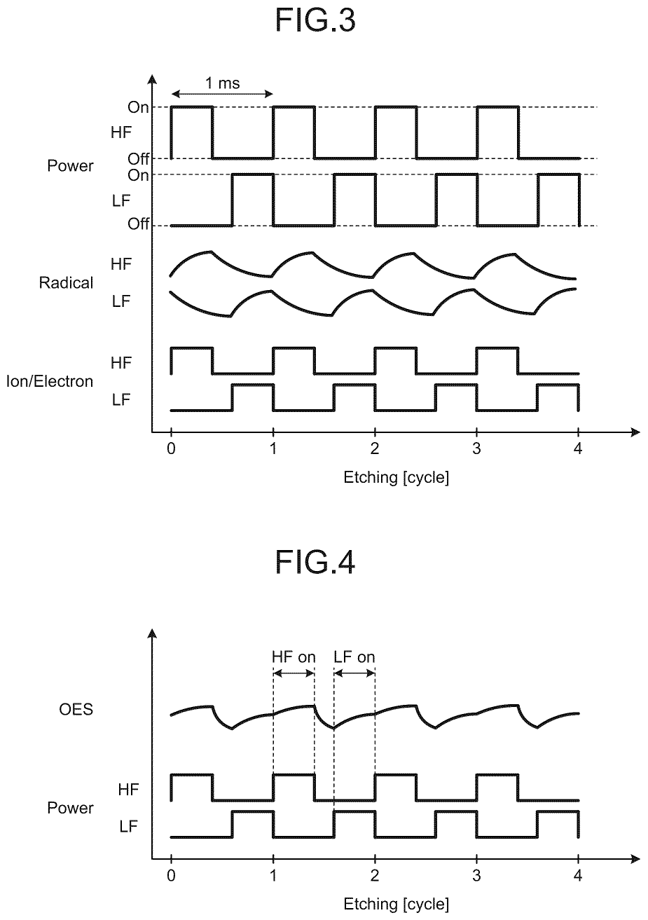

The following specifically describes detection of the end point of the etching. FIG. 3 is a diagram illustrating detection of the end point of the etching according to the first embodiment. FIG. 3 illustrates periods during which the source RF signal and the bias RF signal are supplied. “HF” shows a period during which the source RF signal is supplied. “LF” shows a period during which the bias RF signal is supplied. The source RF signal and the bias RF signal are each supplied in the On period. In FIG. 3, the source RF signal and the bias RF signal are supplied each in a pulse form without their periods overlapping. In FIG. 3, the frequency of the pulses turning on and off the source RF signal and the bias RF signal is set to 1 kHz, and the source RF signal and the bias RF signal are turned on and off at a cycle of 1 ms to perform the cycle etching.

FIG. 3 illustrates the follow-up characteristics of radicals (Radical) and ions and electrons (Ion/Electron) contained in the plasma. The radicals have a follow-up to the on and off of the radio-frequency power of 1 ms or longer. Thus, in one cycle of on and off, radicals generated at different pulse levels are mixed. For example, in a period with LF being on, radicals in the previous period with HF being on and radicals with LF being on are mixed. Thus, when detecting the end point of the etching for radicals such as bi-products produced at a specific pulse level, radicals generated at other pulse levels and their trailing around a signal wavelength become noise. For example, in the period with LF being on, radicals in the previous period with HF being on become noise.

On the other hand, the ions and electrons have a follow-up to the on and off of the radio-frequency power of 0.1 ms or shorter. Thus, the cycle etching using RF pulses with 100 Hz to 10 kHz does not cause interference caused by different pulse levels.

FIG. 4 is a diagram illustrating conventional detection of an end point of etching. In the case of the cyclic etching, in the plasma, radicals generated at different pulse levels are mixed as described above. Thus, even if the emission intensity of the plasma during the etching is detected by an OES and the end point of the etching is attempted to be detected from a change in the detected emission intensity, the end point of the etching cannot be accurately detected. For example, even if the end point of the etching is attempted to be detected from a change in the emission intensity of the plasma in a period with LF being on, emission by radicals in a period with HF being on is mixed in the period with LF being on, and thus the end point of the etching cannot be accurately detected.

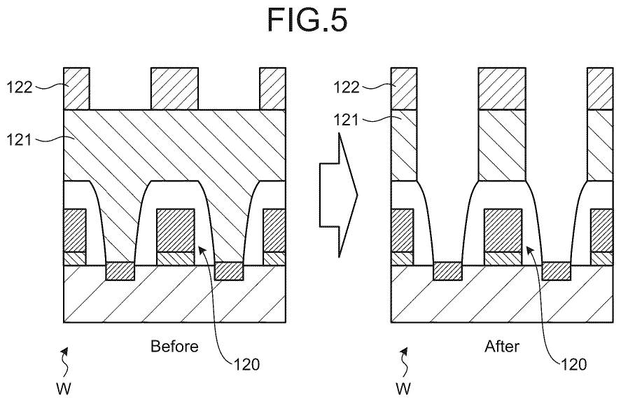

The following describes an example of detection of the end point of the etching. FIG. 5 is a diagram of an example of the substrate W to be etched according to the first embodiment. This drawing illustrates a case in which a self-aligned contact (SAC) process is performed on the substrate W. The substrate W is formed with a plurality of transistors 120. A SiO2 film 121 such as a silicon dioxide film is formed on the transistors 120. A pattern 122 is formed on the oxide film 121. In the SAC process, the oxide film 121 is etched using the pattern 122 as a mask. For example, the plasma processing apparatus 1 performs etching of the oxide film 121 in the SAC process by cycle etching using a processing gas containing a C4F6 gas, an Ar gas, and a O2 gas as an etching gas. During the etching, the component of the etched oxide film 121 is continuously released into the plasma, but when the etching of the oxide film 121 ends, there is no more release of the component of the oxide film 121, and the plasma characteristics change. The detector 102b detects the end of the etching from the change in any of the voltage, the current, and the phase difference between the voltage and the current measured by the measuring unit 35.

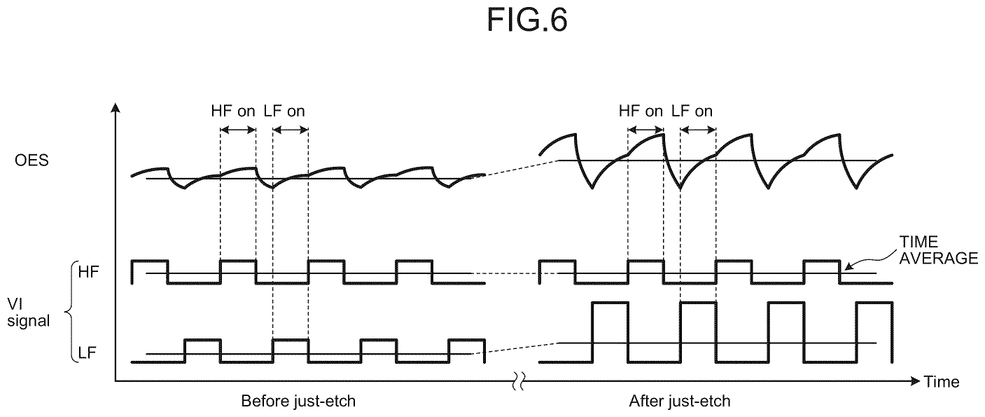

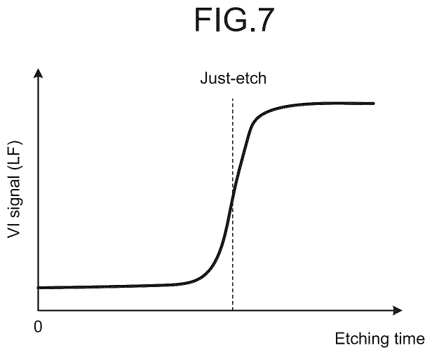

FIG. 6 is a diagram illustrating detection of the end point of the etching according to the first embodiment. FIG. 6 schematically illustrates changes in emission intensity measured by the OES in a period before just-etch (Before just-etch), when the etching of the oxide film 121 just ends, and a period after just-etch (After just-etch). In the signal measured by the OES, an HF on signal and an LF on signal overlap, and thus the end point of the etching cannot be accurately detected. FIG. 6 also schematically illustrates changes in the signal (VI signal) measured by the measuring unit 35 in each period in which HF and LF are supplied in the period before just-etch and the period after just-etch. The signal (VI signal) schematically shows changes in the voltage or the current measured by the measuring unit 35, and the signal is shown in a separate manner as “HF” and “LF” in correspondence with the periods in which HF and LF are each supplied. The “HF” signal shows a small change between before just-etch and after just-etch. On the other hand, the “LF” signal changes significantly between before just-etch and after just-etch. FIG. 7 is a diagram illustrating an example of detection of the end of the etching according to the first embodiment. FIG. 7 illustrates a change in the “LF” signal (VI signal) while the oxide film 121 is etched. The “LF” signal changes significantly before and after the timing of the just-etch of the oxide film 121. Thus, the end of the etching can be accurately detected by measuring the change in the voltage or the current in the period during which LF is supplied.

The detector 102b detects the status of the etching from the voltage or the current of the signal input from the measuring unit 35. For example, the detector 102b detects the end of the etching of the oxide film 121 as the status of the etching from the change in any of the voltage, the current, and the phase difference between the voltage and the current measured by the measuring unit 35 in the period during which the bias RF signal is supplied. The detector 102b monitors in real time the voltage, the current, and the phase difference between the voltage and the current measured by the measuring unit 35 and regards a moment with a significant change as the end point of the etching. The detector 102b may apply common mathematical methods for reducing noise, such as moving averaging and time differentiating, to data processing detecting the end point. The measuring unit 35 may extract a signal with a specific frequency by passing a frequency filter through the signal of the voltage or the current.

During the cycle etching, for example, if the end point of the etching is detected from the moving average of the signal continuously measured by the VI probe as in the conventional technology, signals in periods other than the period during which LF is supplied become noise, and the end point of the etching cannot be accurately detected.

On the other hand, in the cycle etching according to the present embodiment illustrated in FIG. 3, the period during which the bias RF signal is supplied most contributes to the etching and the selection ratio. Thus, the detector 102b can accurately detect the end of the etching by detecting the end of the etching of the oxide film 121 from the change in any of the voltage, the current, and the phase difference between the voltage and the current measured by the measuring unit 35 in the period during which the bias RF signal is supplied.

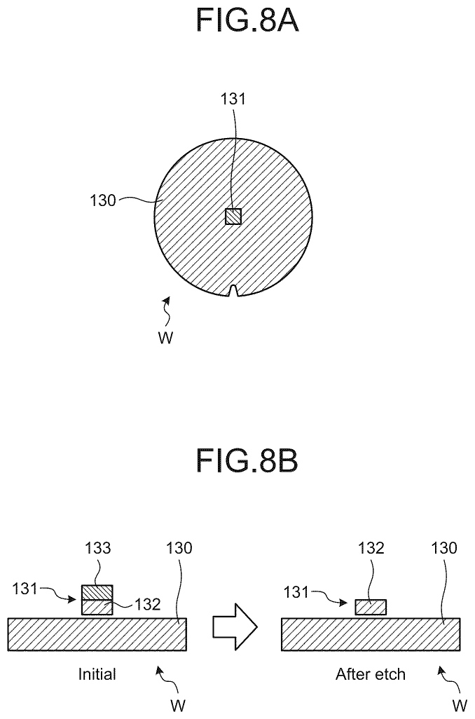

By the way, along with the miniaturization of semiconductor devices, the substrate W has a smaller ratio of an area to be etched. For example, in the substrate W illustrated in FIG. 5, along with miniaturization, the diameter of the opening of the pattern 122 used as a mask has become smaller, and the ratio of the area in which the oxide film 121 is exposed has become smaller. Thus, the following describes the accuracy of detection of the end point of the etching when the ratio of the area to be etched of the substrate W changes. FIG. 8A and FIG. 8B are diagrams of an example of the substrate W according to the first embodiment. FIG. 8A is a top view of the substrate W. FIG. 8B is a side view of the substrate W. The substrate W has a chip 131 provided on a bare wafer 130. The chip 131 has an oxide film 133 such as a SiO2 film formed on a silicon film 132. The substrate W can change the ratio of the area of the oxide film 133 to the surface area of the substrate W by changing the surface area of the chip 131. The substrate W was prepared with the ratio of the area of the oxide film 133 to the surface area of the substrate W being 0%, 0.04%, 0.1%, 0.6%, 1%, and 4% each. Then, etching of the oxide film 133 of each substrate W was performed by the cycle etching by the plasma processing apparatus 1 according to the present embodiment, and a voltage or a current was measured by the measuring unit 35 in the period during which the bias RF signal was supplied.

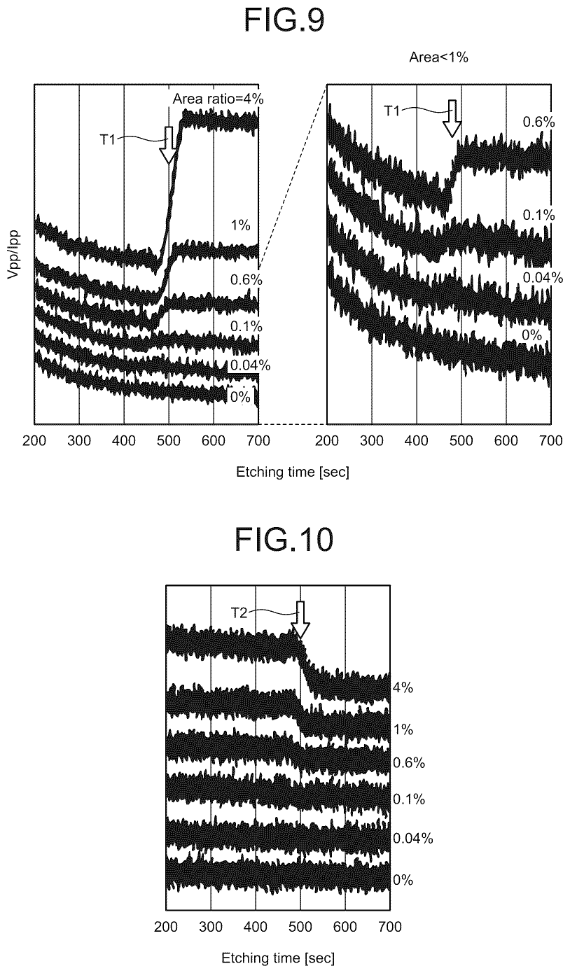

FIG. 9 is a diagram illustrating an example of measurement results by the measuring unit 35 according to the first embodiment. FIG. 9 illustrates the measurement results of the voltage and the current measured by the measuring unit 35 when the substrate W with the area ratio of the oxide film 133 to the surface area of the substrate W being 0%, 0.04%, 0.1%, 0.6%, 1%, and 4% each was subjected to the cycle etching. FIG. 9 illustrates waveforms of changes in the value of VPP/IPP, which is obtained by dividing a peak-to-peak value Vpp of a voltage V measured by the measuring unit 35 by a peak-to-peak value IPP of a current I as the measurement results. That is, FIG. 9 illustrates changes in resistance at the measuring unit 35. Also illustrated on the right side of FIG. 9 is an enlarged view in which the waveforms of the substrate W with 0%, 0.04%, 0.1%, and 0.6% are enlarged. FIG. 9 also illustrates a timing T1 for the just-etch of the oxide film 133. As illustrated in FIG. 9, in the substrate W with 0.04%, 0.1%, 0.6%, 1%, and 4%, the waveform changes before and after the just-etch timing T1, and especially for 0.6% and more, the waveform changes significantly. With this change, the end point of the etching can be detected.

The following describes, as a comparative example, changes in emission intensity measured by the OES. FIG. 10 is a diagram illustrating an example of a measurement result by the OES according to the comparative example. FIG. 10 illustrates waveforms of changes in emission intensity measured by the OES when the substrate W with 0%, 0.04%, 0.1%, 0.6%, 1%, and 4% each described above was subjected to the cycle etching. FIG. 10 also illustrates a timing T2 for the just-etch of the oxide film 133. When FIG. 9 and FIG. 10 are compared to each other, the measurement result by the measuring unit 35 according to the embodiment has a larger change in the waveform before and after just-etch than that of the comparative example and has a better S/n ratio in detection of the end point of the etching. Thus, the measuring unit 35 according to the embodiment can detect the end point of the etching more accurately than in the comparative example.

Described in FIG. 9 as an example is a case in which the end point of the etching is detected from the change in the value of VPP/IPP of the voltage and the current measured by the measuring unit 35. However, this is not limiting. Both the voltage and the current measured by the measuring unit 35 change in the maximum value, the cycle (frequency), the average value, and the effective value of the waveform before and after the just-etch timing T1. Thus, the detector 102b may detect the end point of the etching from a change in the maximum value, the cycle (frequency), the average value, or the effective value of either the voltage or the current or a change in the phase difference between the voltage and the current. The detector 102b may detect the end point of the etching from a change in an impedance value, a reactance value, a power value, or a power factor calculated from the voltage, the current, and the phase difference between the voltage and the current. Also in this case, the detector 102b can accurately detect the end point of the etching.

Described in the first embodiment as an example is a case in which the measuring unit 35 is provided in the conductive part 33b connected to the substrate support 11. However, this is not limiting. The measuring unit 35 is only required to be provided in the electrode disposed inside the plasma processing chamber 10 or the wire connected to the electrode in order to measure the state of the plasma inside the plasma processing chamber 10. For example, the measuring unit 35 may be provided in the conductive part 33a connected to the conductive member of the shower head 13. An electrode for measurement may be disposed inside the plasma processing chamber 10, and the measuring unit 35 may be provided in the electrode or a wire connected to the electrode. In the present embodiment, the measuring unit 35 is provided closer to the substrate support 11 than the impedance matching circuit 34b is in the conductive part 33b. With this configuration, the measuring unit 35 can measure the state of the plasma inside the plasma processing chamber 10.

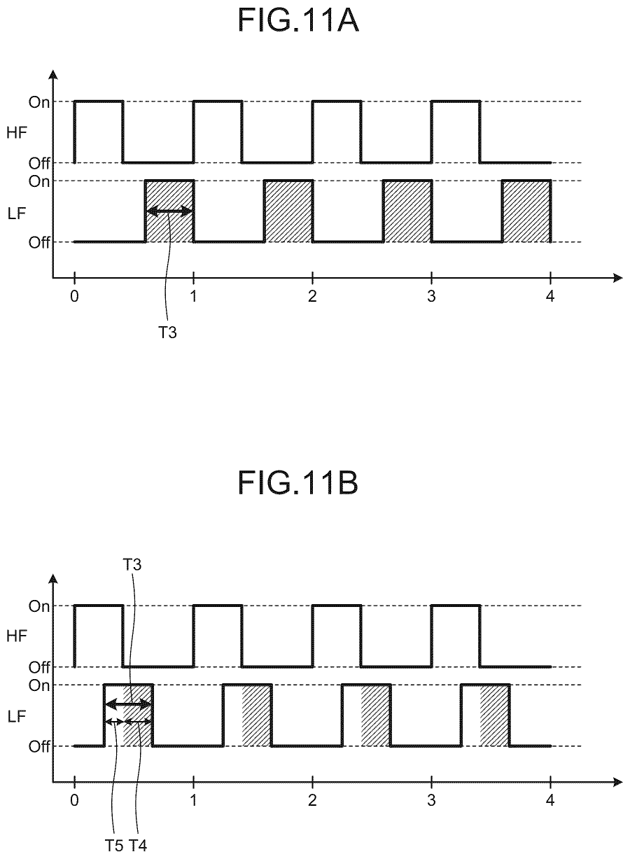

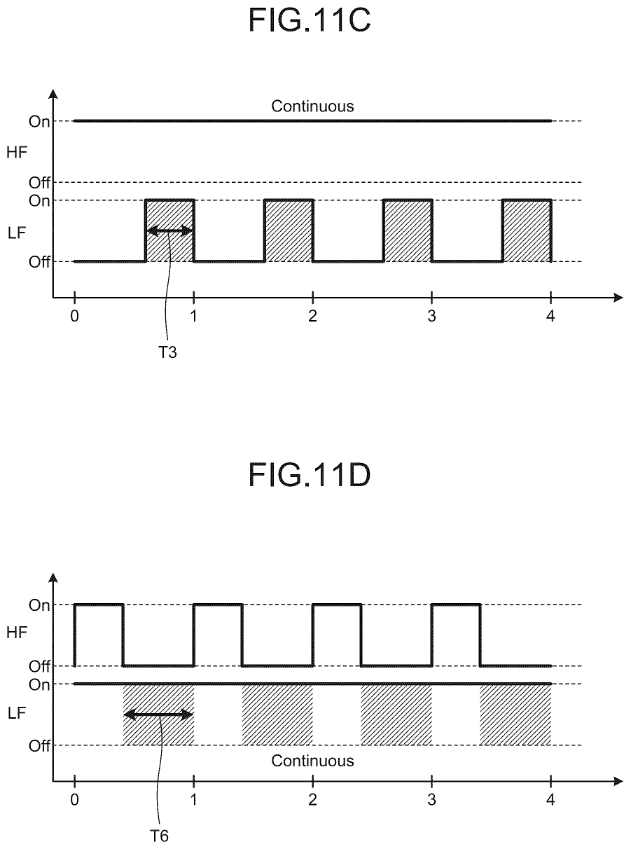

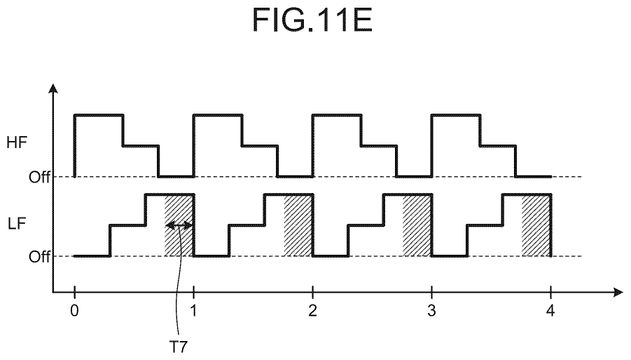

Described in the first embodiment as an example is a case in which the source RF signal and the bias RF signal are supplied each in a pulse form without their periods overlapping. However, this is not limiting. The RF power supply 31 is only required to supply at least either the source RF signal or the bias RF signal in a pulse form. The RF power supply 31 may also change the power of the source RF signal and the bias RF signal. The detector 102b is only required to detect the end point of the etching from the change in any of the voltage, the current, and the phase difference between the voltage and the current measured by the measuring unit 35 with the timing when the combination of the source RF signal and the bias RF signal most contributes to the etching and the selection ratio. FIGS. 11A to 11E are diagrams of examples of the source RF signal and bias RF signal and the period during which the end point of the etching is detected according to the first embodiment. “HF” shows a period during which the source RF signal is supplied. “LF” shows a period during which the bias RF signal is supplied. FIG. 11A illustrates a case in which the source RF signal and the bias RF signal are supplied each in a pulse form from the RF power supply 31 without their periods overlapping as in the embodiment described above. In this case, the detector 102b may detect the end point of the etching from the change in any of the voltage, the current, and the phase difference between the voltage and the current measured by the measuring unit 35 in a period T3, during which the bias RF signal is supplied. FIG. 11B illustrates a case in which the source RF signal and the bias RF signal are supplied each in a pulse form from the RF power supply 31 with their periods partially overlapping. In this case, the detector 102b may detect the end point of the etching from the change in any of the voltage, the current, and the phase difference between the voltage and the current measured by the measuring unit 35 in a period T4, during which only the bias RF signal is supplied. In FIG. 11B, the detector 102b uses the period T4, which is the period T3, during which the bias RF signal is supplied, excluding a period T5, which overlaps with the source RF signal, as the period for detecting the end point of the etching. FIG. 11C illustrates a case in which the bias RF signal is supplied in a pulse form, while the source RF signal is continuously supplied from the RF power supply 31. In this case, the detector 102b detects the end point of the etching from the change in any of the voltage, the current, and the phase difference between the voltage and the current measured by the measuring unit 35 in the period T3, during which the bias RF signal is supplied. FIG. 11D illustrates a case in which the source RF signal is supplied in a pulse form, while the bias RF signal is continuously supplied from the RF power supply 31. In this case, the detector 102b detects the end point of the etching from the change in any of the voltage, the current, and the phase difference between the voltage and the current measured by the measuring unit 35 in a period T6, during which the source RF signal is turned off and only the bias RF signal is supplied. FIG. 11E illustrates a case in which the source RF signal and the bias RF signal are supplied each in a pulse form from the RF power supply 31 with their periods partially overlapping. In addition, the source RF signal and the bias RF signal change in power during the on period. In this case, the detector 102b detects the end point of the etching from the change in any of the voltage, the current, and the phase difference between the voltage and the current measured by the measuring unit 35 in a period T7, during which only the bias RF signal is supplied.

Described in the first embodiment as an example is end point detection when the SAC process is performed by the cycle etching in FIG. 5. However, this is not limiting. Any cycle etching process can be applied to end point detection. For example, the embodiment can be applied to end point detection when the back end of line (BEOL) process or the middle of the line (MOL) process is performed by the cycle etching.

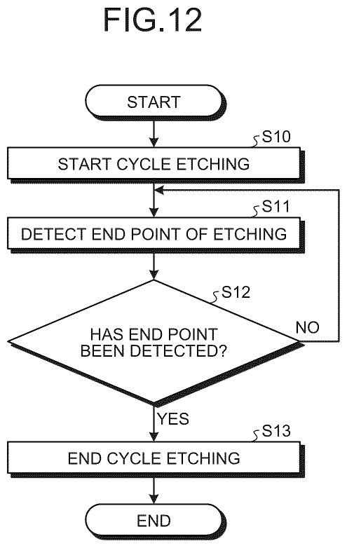

The following describes a processing procedure of a method for detecting an end point performed by the plasma processing apparatus 1 according to the first embodiment. FIG. 12 is a diagram illustrating an example of a processing procedure of the method for detecting an end point according to the first embodiment. In the first embodiment, the end point of the etching is detected by the method for detecting an end point. The processing of the method for detecting an end point illustrated in FIG. 12 is executed when the substrate W formed with a film to be etched is placed on the substrate support 11 and the cycle etching is performed.

The plasma controller 102a starts the cycle etching (S10). For example, the plasma controller 102a controls the exhaust system 40 to exhaust the inside of the plasma processing chamber 10 to a certain degree of vacuum. The plasma controller 102a controls the gas supply unit 20 to introduce the processing gas from the gas supply unit 20 into the plasma processing space 10s. The plasma controller 102a controls the power supply 30 to supply at least either the source RF signal or the bias RF signal in a pulse form from the first RF generation unit 31a and the second RF generation unit 31b in sync with the introduction of the processing gas so as to start the cycle etching.

The detector 102b detects the end point of the etching from the change in any of the voltage, the current, and the phase difference between the voltage and the current measured by the measuring unit 35 in the period during which the bias RF signal is supplied (S11). For example, the detector 102b detects the end of the etching of the film to be etched from the change in any of the voltage, the current, and the phase difference between the voltage and the current measured by the measuring unit 35. The detector 102b monitors in real time the voltage, the current, and the phase difference between the voltage and the current measured by the measuring unit 35 and regards a moment with a significant change as the end point of the etching.

The plasma controller 102a determines whether the end point of the etching has been detected by the detector 102b (S12). If the end point of the etching has not been detected (No at S12), the process moves to S11.

On the other hand, if the end point of the etching has been detected (Yes at S12), the plasma controller 102a ends the cycle etching (S13) and ends the process.

As described above, the plasma processing apparatus 1 according to the first embodiment has the plasma processing chamber 10, the conductive member of the substrate support 11 (the electrode), the measuring unit 35, the gas supply unit 20, the RF power supply 31 (a radio-frequency power supply), and the detector 102b. The plasma processing chamber 10 is provided inside with the substrate support 11 (a placing pedestal) on which the substrate W is placed. The conductive member of the substrate support 11 is disposed inside the plasma processing chamber 10. The measuring unit 35 is provided in the conductive member of the substrate support 11 or the conductive part 33b (wire) connected to the conductive member of the substrate support 11, and measures either the voltage or the current. The gas supply unit 20 supplies the gas to be made into plasma into the plasma processing chamber 10. The RF power supply 31 supplies, to the plasma processing chamber 10, the radio-frequency power in a pulse form making the gas supplied into the plasma processing chamber 10 plasma. The detector 102b detects the end point of the plasma processing from the change in any of the voltage, the current, and the phase difference between the voltage and the current measured by the measuring unit 35 with the timing synchronized with the cycle of the pulses of the radio-frequency power. With this operation, the plasma processing apparatus 1 can accurately detect the end point of the plasma processing.

The gas supply unit 20 supplies the etching gas as the gas to be made into plasma. The detector 102b detects the end point of the etching from the change in any of the voltage, the current, and the phase difference between the voltage and the current measured by the measuring unit 35 with the timing synchronized with the cycle of the pulses of the radio-frequency power. With this operation, the plasma processing apparatus 1 can accurately detect the end point of the etching.

The RF power supply 31 supplies, to the substrate, at least either the source RF signal (the first radio-frequency power) for generating plasma or the bias RF signal (the second radio-frequency power) for drawing the ion component in the plasma, in a pulse form. The detector 102b detects the end point of the etching from the change in any of the voltage, the current, and the phase difference between the voltage and the current measured by the measuring unit 35 with the timing when the combination of the source RF signal and the bias RF signal supplied most contributes to the etching and the selection ratio. With this operation, the plasma processing apparatus 1 can accurately detect the end point of the etching.

The detector 102b detects the end point of the etching from the change in any of the voltage, the current, and the phase difference between the voltage and the current measured by the measuring unit 35 in the period during which the bias RF signal is supplied. With this operation, the plasma processing apparatus 1 can accurately detect the end point of the etching.

The RF power supply 31 supplies the source RF signal and the bias RF signal each in a pulse form with the periods during which the source RF signal and the bias RF signal are supplied partially overlapping or without the periods during which the source RF signal and the bias RF signal are supplied overlapping. The detector 102b detects the end point of the etching from the change in any of the voltage, the current, and the phase difference between the voltage and the current measured by the measuring unit 35 in the period during which only the bias RF signal is supplied. With this operation, the plasma processing apparatus 1 can accurately detect the end point of the etching.

The RF power supply 31 supplies the radio-frequency power in a pulse form with a frequency of 100 Hz to 10 kHz. With this configuration, the plasma processing apparatus 1 can detect the end point of the etching more accurately than when the end point of the etching is detected by the OES.

The electrode is provided in the substrate support 11. The conductive part 33b connected to the electrode is provided with the impedance matching circuit 34b, and the radio-frequency power is supplied from the RF power supply 31. The measuring unit 35 is provided closer to the electrode than the impedance matching circuit 34b is in the conductive part 33b. With this configuration, the plasma processing apparatus 1 can accurately measure the state of the plasma from the voltage or the current measured by the measuring unit 35 and can thus accurately detect the end point of the etching.

The substrate W is formed with the film (the oxide film 121) to be etched. The detector 102b detects the end of the etching of the film (the oxide film 121). With this operation, the plasma processing apparatus 1 can accurately detect the end point of the etching of the film to be etched.

### Second Embodiment

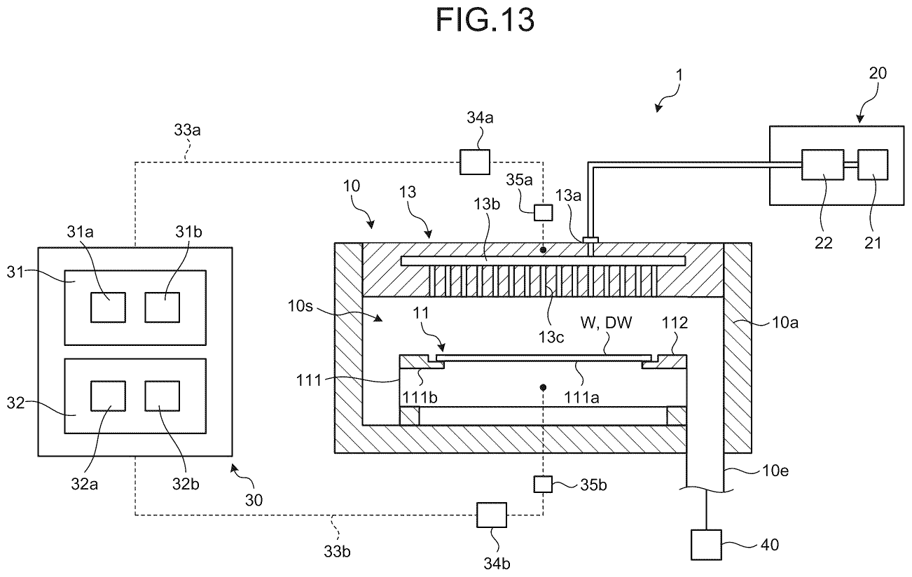

The following describes a second embodiment. The second embodiment describes a case of detecting the end point of the plasma processing cleaning the inside of the plasma processing chamber. FIG. 13 is a diagram of an example of a schematic configuration of the plasma processing apparatus 1 according to the second embodiment. The plasma processing apparatus 1 according to the second embodiment has a configuration similar in part to that of the plasma processing apparatus 1 according to the first embodiment illustrated in FIG. 1, and thus the same parts are denoted by the same symbols to omit descriptions thereof, and the following mainly describes different parts.

The plasma processing apparatus 1 is provided with the measuring unit 35 measuring either a voltage or a current in the electrode disposed inside the plasma processing chamber 10 or the wire connected to the electrode. The plasma processing apparatus 1 according to the second embodiment is provided with a measuring unit 35a in the conductive part 33a connected to the conductive member of the shower head 13. The plasma processing apparatus 1 according to the second embodiment is provided with a measuring unit 35b in the conductive part 33b connected to the conductive member of the substrate support 11. The measuring units 35a and 35b include a probe detecting a current or a voltage. The measuring units 35a and 35b measure the voltage or the current. The measuring unit 35a measures the voltage or the current of the conductive part 33a through which the source RF signal passes. The measuring unit 35a outputs a signal indicating the voltage or the current measured to the controller 100. The measuring unit 35b measures the voltage or the current of the conductive part 33b through which the bias RF signal passes. The measuring unit 35b outputs a signal indicating the voltage or the current measured to the controller 100.

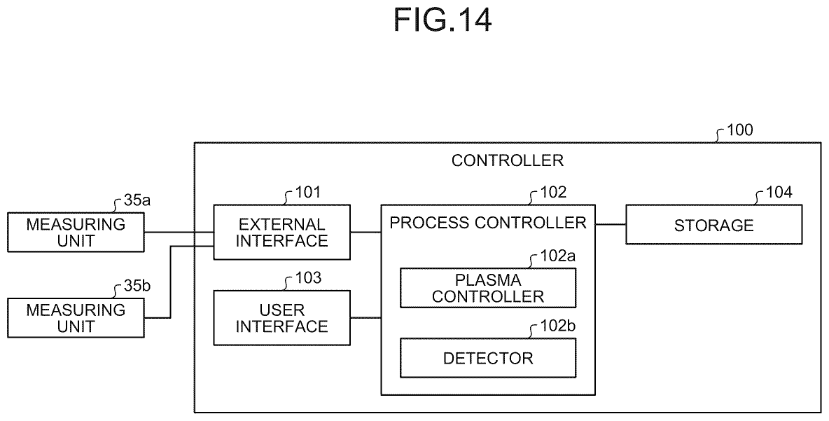

FIG. 14 is a block diagram of an example of a schematic configuration of the controller 100 according to the second embodiment. The controller 100 according to the second embodiment has a configuration similar in part to that of the controller 100 according to the first embodiment illustrated in FIG. 2, and thus the same parts are denoted by the same symbols to omit descriptions thereof, and the following mainly describes different parts. The controller 100 comprehensively controls the operation of the plasma processing apparatus 1 illustrated in FIG. 14.

The external interface 101 is made communicable with the parts of the plasma processing apparatus 1 and receives input of and outputs various kinds of data. For example, the external interface 101 receives input of the signals indicating the voltage or the current measured by the measuring units 35a and 35b.

The plasma controller 102a controls the plasma processing. For example, the plasma controller 102a controls plasma cleaning removing a deposition adhering inside the plasma processing chamber 10. The plasma controller 102a controls the exhaust system 40 to exhaust the inside of the plasma processing chamber 10 to a certain degree of vacuum. The plasma controller 102a controls the gas supply unit 20 to introduce a cleaning gas from the gas supply unit 20 into the plasma processing space 10s. The cleaning gas may be any gas so long as it can remove the deposition and the like adhering inside the plasma processing chamber 10. Examples of the cleaning gas include oxygen-containing gases such as a O2 gas. The plasma controller 102a controls the power supply 30 to supply the source RF signal and the bias RF signal from the first RF generation unit 31a and the second RF generation unit 31b in sync with the introduction of the cleaning gas so as to generate plasma inside the plasma processing chamber 10. The frequency of the source RF signal is set to a frequency in a range of 40 MHz to 130 MHz. The frequency of the bias RF signal is set to a frequency lower than the first frequency of the source RF signal and in a range of 400 kHz to 40 MHz.

The plasma processing apparatus 1 according to the second embodiment repeats RF power in a pulse form to perform plasma cleaning. The plasma controller 102a controls the RF power supply 31 to supply the radio-frequency power from the RF power supply 31 in a pulse form. The RF power supply 31 supplies at least either the source RF signal or the bias RF signal in a pulse form. For example, the plasma controller 102a controls the RF power supply 31 to supply the source RF signal and the bias RF signal each in a pulse form from the first RF generation unit 31a and the second RF generation unit 31b. The frequency of the pulses turning on and off the supply of the source RF signal and the bias RF signal is set to 100 Hz to 10 kHz. In the following, out of the source RF signal and the bias RF signal, the source RF signal with a higher frequency is also referred to as high frequency (HF) and the bias RF signal with a lower frequency is also referred to as low frequency (LF).

FIG. 15 is a diagram illustrating an example of supply of radio-frequency power according to the second embodiment. FIG. 15 illustrates periods during which the source RF signal and the bias RF signal are supplied and supply power (Power). “HF” shows a period during which the source RF signal is supplied. “LF” shows a period during which the bias RF signal is supplied. The source RF signal and the bias RF signal are each supplied in the On period. In FIG. 15, the source RF signal and the bias RF signal are supplied each in a pulse form without their periods overlapping. In FIG. 15, the frequency of the pulses turning on and off the source RF signal and the bias RF signal is set to 1 kHz, and the source RF signal and the bias RF signal are turned on and off with a cycle of 1 ms to perform the cleaning.

The detector 102b detects the end point of the plasma processing from the voltage or the current of the signals input from the measuring units 35a and 35b. For example, the detector 102b detects the end point of the plasma processing from a change in any of a voltage, a current, and a phase difference between the voltage and the current measured by the measuring units 35a and 35b with the timing synchronized with the cycle of the pulses of the radio-frequency power. In the present embodiment, the detector 102b detects an end point of the cleaning from the change in any of the voltage, the current, and the phase difference between the voltage and the current measured by the measuring units 35a and 35b with the timing synchronized with the cycle of the pulses of the radio-frequency power. The detector 102b detects the end point of the cleaning from the change in any of the voltage, the current, and the phase difference between the voltage and the current measured by the measuring units 35a and 35b with a timing when a combination of the source RF signal and the bias RF signal supplied most contributes to the cleaning. For example, upon supply of the source RF signal, the plasma processing chamber 10 forms a path for the source RF signal to pass near the upper electrode (for example, the shower head 13), generating plasma near the top of the inside. Thus, the period during which the source RF signal is supplied most contributes to the cleaning of the area near the upper electrode (for example, the shower head 13) inside the plasma processing chamber 10. The detector 102b detects the end point of the cleaning of the area near the upper electrode inside the plasma processing chamber 10 from the change in any of the voltage, the current, and the phase difference between the voltage and the current measured by the measuring unit 35a in the period during which the source RF signal is supplied. Upon supply of the bias RF signal, the plasma processing chamber 10 forms a path for the bias RF signal to pass near the lower electrode (for example, the substrate support 11), generating plasma near the lower electrode. Thus, the period during which the bias RF signal is supplied most contributes to the cleaning of the area near the lower electrode (for example, the substrate support 11) inside the plasma processing chamber 10. The detector 102b detects the end point of the cleaning of the area near the lower electrode inside the plasma processing chamber 10 from the change in any of the voltage, the current, and the phase difference between the voltage and the current measured by the measuring unit 35b in the period during which the bias RF signal is supplied.

The plasma controller 102a controls the plasma processing based on a detection result by the detector 102b. For example, the plasma controller 102a ends the cleaning upon detection of the end point of the cleaning by the detector 102b.

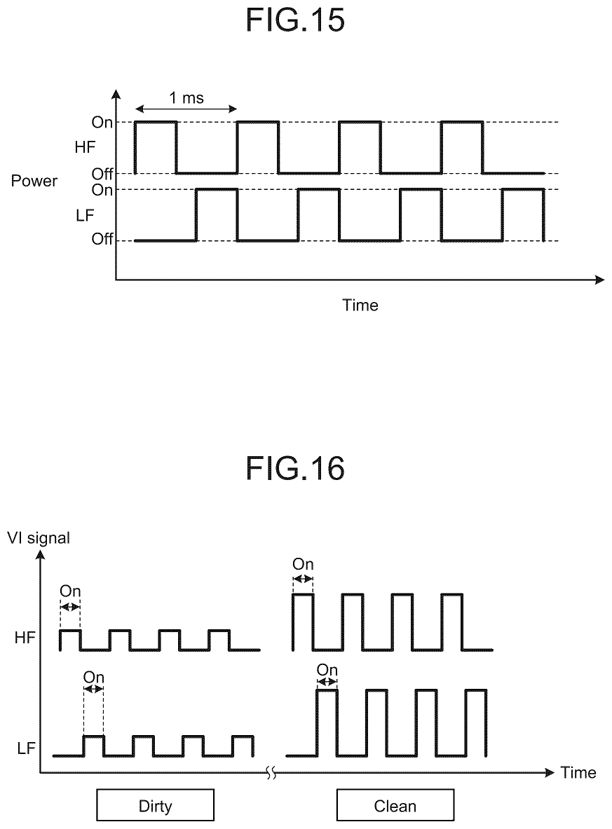

The following specifically describes detection of the end point of the cleaning. FIG. 16 is a diagram illustrating detection of the end point of the cleaning according to the second embodiment. FIG. 16 schematically illustrates changes in the signal (VI signal) measured by the measuring units 35a and 35b. FIG. 16 schematically illustrates changes in the signal (VI signal) in a state in which the deposition adheres inside the plasma processing chamber 10 (Dirty) and a state in which the deposition inside the plasma processing chamber 10 has been removed (Clean). The signal (VI signal) schematically shows changes in the voltage or the current measured by the measuring units 35a and 35b, and the signal is shown in a separate manner as “HF” and “LF” in correspondence with the periods in which HF and LF are each supplied. In FIG. 16, the signal (VI signal) shows the voltage. “HF” schematically shows changes in the voltage measured by the measuring unit 35a by the source RF signal. “LF” schematically shows changes in the voltage measured by the measuring unit 35b by the bias RF signal. The source RF signal and the bias RF signal are each supplied in the On period. FIG. 16 illustrates the On period for each of the source RF signal and the bias RF signal. “HF” increases in a voltage change in correspondence with the period during which the source RF signal is On. “LF” increases in a voltage change in correspondence with the period during which the bias RF signal is On.

The voltage measured by the measuring units 35a and 35b in the period during which the source RF signal and the bias RF signal are each On changes by the deposition inside the plasma processing chamber 10 being removed. For example, as illustrated in FIG. 16, the voltage measured by the measuring units 35a and 35b in the period during which the source RF signal and the bias RF signal are each On increases by the inside of the plasma processing chamber 10 changing from Dirty to Clean.

The area near the upper electrode inside the plasma processing chamber 10 is cleaned by the plasma generated by the source RF signal. The plasma near the upper electrode is affected by the deposition and the like near the upper electrode. Thus, the voltage measured by the measuring unit 35a in the period during which the source RF signal is On changes depending on the status of cleaning of the deposition near the upper electrode. For example, as illustrated in FIG. 16, the voltage measured by the measuring unit 35a in the period during which the source RF signal is On increases by the deposition of the shower head 13 inside the plasma processing chamber 10 being removed. Thus, the end point of the cleaning of the shower head 13 can be detected from the change in the voltage measured by the measuring unit 35a in the period during which the source RF signal is On.

The area near the lower electrode inside the plasma processing chamber 10 is cleaned by the plasma generated by the bias RF signal. The plasma near the lower electrode is affected by the deposition and the like near the lower electrode. Thus, the voltage measured by the measuring unit 35b in the period during which the bias RF signal is On changes depending on the status of cleaning of the deposition near the lower electrode. For example, as illustrated in FIG. 16, the voltage measured by the measuring unit 35b in the period during which the bias RF signal is On increases by the deposition of the substrate support 11 inside the plasma processing chamber 10 being removed. Thus, the end point of the cleaning of the substrate support 11 can be detected from the voltage measured by the measuring unit 35b in the period during which the bias RF signal is On.

In the present embodiment, the detector 102b detects the end point of the cleaning of the shower head 13 part inside the plasma processing chamber 10 from the change in the voltage measured by the measuring unit 35a in the period during which the source RF signal is On. The detector 102b detects the end point of the cleaning of the substrate support 11 part inside the plasma processing chamber 10 from the change in the voltage measured by the measuring unit 35b in the period during which the bias RF signal is On.

The change in the voltage in the period during which the bias RF signal and the source RF signal are On illustrated in FIG. 16 is by way of example, and the change in the voltage is not limited to this example. For example, depending on the configuration of the plasma processing apparatus 1 and other factors, the removal of the deposition may result in a change in the voltage reducing. In such a case also, the end point of the cleaning can be detected from the change in the voltage.

The current and the phase difference between the voltage and the current measured by the measuring units 35a and 35b in the period during which the bias RF signal and the source RF signal are On change by the deposition being removed as in the voltage. Thus, the detector 102b can detect the end point of the cleaning of the inside of the plasma processing chamber 10 from the change in the voltage, the current, and the phase difference between the voltage and the current measured by the measuring units 35a and 35b in the period during which the bias RF signal and the source RF signal are On. For example, the detector 102b may monitor in real time the voltage, the current, and the phase difference between the voltage and the current measured by the measuring units 35a and 35b and regard a moment when the deposition has changed significantly enough to be regarded as being removed as the end point of the cleaning.

The following briefly describes a procedure of cleaning the inside of the plasma processing chamber 10 by the plasma processing apparatus 1 according to the second embodiment. When the cleaning is performed, a dummy wafer DW for cleaning is placed on the substrate support 11 as the substrate W. Dummy wafers DW are replaced as needed during the cleaning. The plasma processing apparatus 1 performs exhaustion by the exhaust system 40 to exhaust the inside of the plasma processing chamber 10 to a certain degree of vacuum. The plasma processing apparatus 1 then introduces the cleaning gas from the gas supply unit 20 into the plasma processing space 10s. The plasma processing apparatus 1 supplies the source RF signal and the bias RF signal in a pulse form from the first RF generation unit 31a and the second RF generation unit 31b in sync with the introduction of the cleaning gas to generate plasma inside the plasma processing chamber 10 so as to perform the cleaning. The plasma processing apparatus 1 detects the end point of the cleaning from the change in any of the voltage, the current, and the phase difference between the voltage and the current measured by the measuring units 35a and 35b with the timing synchronized with the cycle of the pulses of the source RF signal and the bias RF signal. For example, the plasma processing apparatus 1 detects the end point of the cleaning from the change in the voltage measured by the measuring units 35a and 35b in the period during which the source RF signal and the bias RF signal are each On.

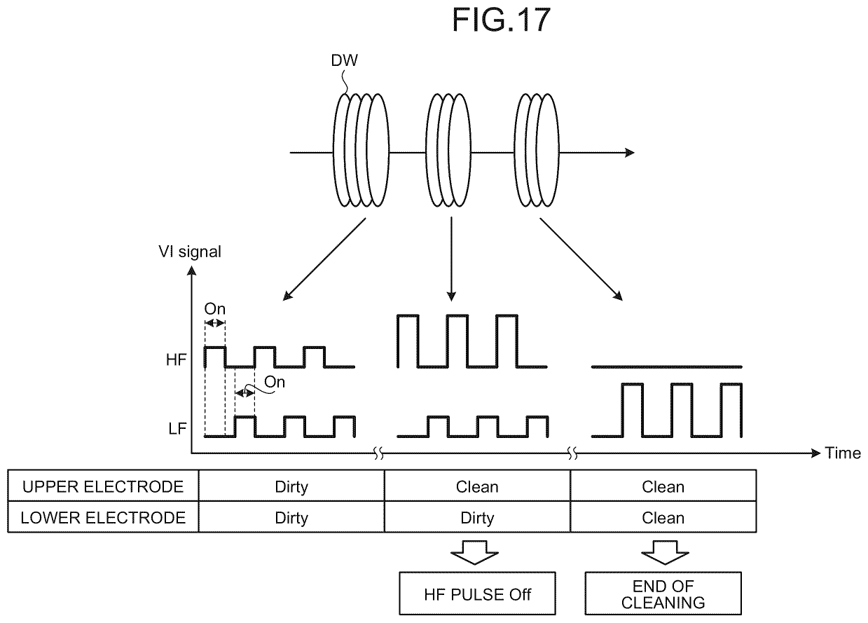

FIG. 17 is a diagram illustrating a procedure of the cleaning according to the second embodiment. FIG. 17 schematically illustrates changes in the signal (VI signal) measured by the measuring units 35a and 35b. The signal (VI signal) schematically shows changes in the voltage or the current measured by the measuring units 35a and 35b, and the signal is shown in a separate manner as “HF” and “LF” in correspondence with the periods in which HF and LF are each supplied. In FIG. 17, the signal (VI signal) shows the voltage. “HF” schematically shows changes in the voltage measured by the measuring unit 35a by the source RF signal. “LF” schematically shows changes in the voltage measured by the measuring unit 35b by the bias RF signal. FIG. 17 illustrates a state of a deposition near the upper electrode (for example, the shower head 13) and near the lower electrode (for example, the substrate support 11) inside the plasma processing chamber 10. Dirty is a state in which the deposition adheres. Clean is a state in which the deposition has been removed. In FIG. 17, the area near the upper electrode and the area near the lower electrode are both Dirty, but the cleaning causes the area near the upper electrode to become Clean and then causes the area near the lower electrode to become Clean. The voltage measured by the measuring unit 35a in the period during which the source RF signal is On rises when the area near the upper electrode becomes Clean. The voltage measured by the measuring unit 35b in the period during which the bias RF signal is On rises when the area near the lower electrode becomes Clean.

The plasma processing apparatus 1 detects the end point of the cleaning of each of the area near the upper electrode and the area near the lower electrode from the change in the voltage measured by the measuring units 35a and 35b in the period during which the source RF signal and the bias RF signal are each On. For example, the plasma processing apparatus 1 detects the end point of the cleaning of the shower head 13 from the change in the voltage measured by the measuring unit 35a in the period during which the source RF signal is On rising. The plasma processing apparatus 1 detects the end point of the cleaning of the area near the substrate support 11 from the change in the voltage measured by the measuring unit 35b in the period during which the bias RF signal is On rising.

Upon detection of the end point of the cleaning of the area near the upper electrode, the plasma processing apparatus 1 stops supply of the source RF signal. With this operation, the plasma near the upper electrode disappears, and the cleaning of the area near the upper electrode stops. Upon detection of the end point of the cleaning of the area near the lower electrode, the plasma processing apparatus 1 stops supply of the bias RF signal. With this operation, the plasma near the lower electrode disappears, and the cleaning of the area near the lower electrode stops.

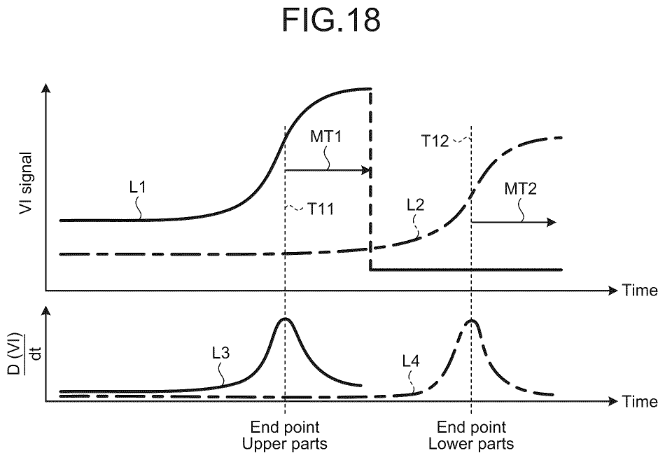

FIG. 18 is a diagram illustrating an example of a procedure of detecting the end point of the cleaning according to the second embodiment. FIG. 18 illustrates a line L1 schematically showing a change in the signal (VI signal) measured by the measuring unit 35a in the period during which the source RF signal is On and a line L2 schematically showing a change in the signal (VI signal) measured by the measuring unit 35b in the period during which the bias RF signal is On. The lines L1 and L2 each show, for example, a change in the average of the voltage in the On period. FIG. 18 also illustrates a line L3 showing a time derivative of the line L1 and a line L4 showing a time derivative of the line L2. The line L3 shows a change amount per unit time of the line L1. The line L4 shows a change amount per unit time of the line L2.

When the area near the upper electrode becomes Clean, as shown in the line L1, the voltage in the period during which the source RF signal is On rises. The plasma processing apparatus 1 detects the end point of the cleaning of the area near the upper electrode from the change in the voltage shown in the line L1. For example, the plasma processing apparatus 1 differentiates the voltage shown in the line L1 over time to determine a change amount per unit time shown in the line L3 and detects the end point of the cleaning of the area near the upper electrode based on a timing T11, at which the change amount peaks. For example, the plasma processing apparatus 1 detects a timing when a certain margin time MT1 has elapsed from the timing T11 as the end point of the cleaning of the area near the upper electrode. The margin time MT1 is the time elapsed from the timing T11 when it is regarded that the deposition near the upper electrode has been removed to become Clean. The margin time MT1 is determined by, for example, an experiment or simulation.

When the area near the lower electrode becomes Clean, as shown in the line L2, the voltage in the period during which the bias RF signal is On rises. The plasma processing apparatus 1 detects the end point of the cleaning of the area near the lower electrode from the change in the voltage shown in the line L2. For example, the plasma processing apparatus 1 differentiates the voltage shown in the line L2 over time to determine a change amount per unit time shown in the line L4 and detects the end point of the cleaning of the area near the lower electrode based on a timing T12, at which the change amount peaks. For example, the plasma processing apparatus 1 detects a timing when a certain margin time MT2 has elapsed from the timing T12 as the end point of the cleaning of the area near the lower electrode. The margin time MT2 is the time elapsed from timing T12 when it is regarded that the deposition near the lower electrode has been removed to become Clean. The margin time MT2 is also determined by, for example, an experiment or simulation.

The detector 102b may detect a timing when the rise in the voltage shown in the line L1 is saturated as the end point of the cleaning of the area near the upper electrode. The detector 102b may detect a timing when the rise in the voltage shown in the line L2 is saturated as the end point of the cleaning of the area near the lower electrode.

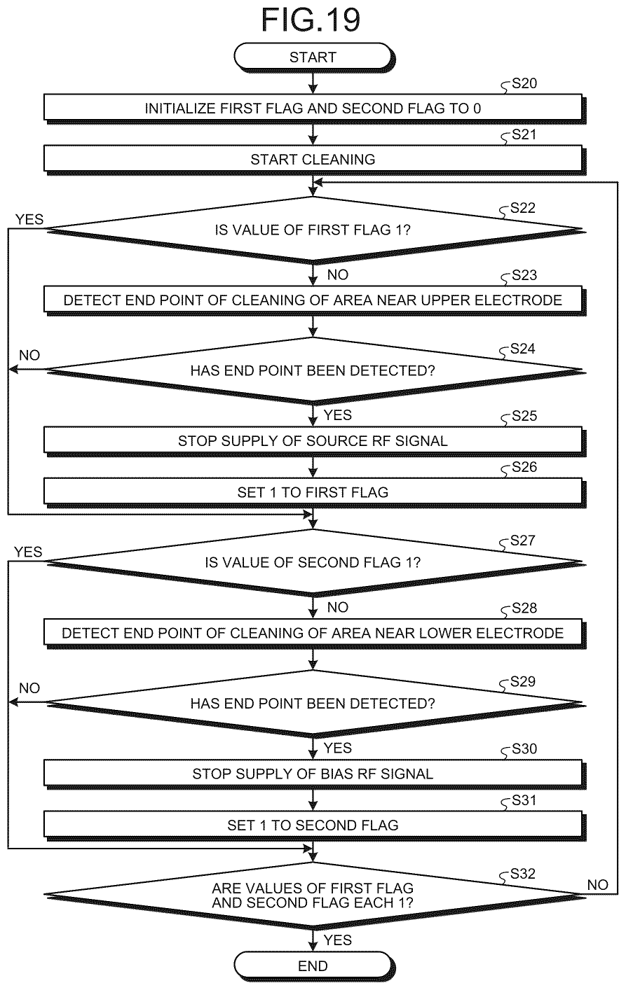

The following describes a processing procedure of a method for detecting an end point performed by the plasma processing apparatus 1 according to the second embodiment. In the second embodiment, the end point of the cleaning is detected by the method for detecting an end point. FIG. 19 is a diagram illustrating an example of a processing procedure of the method for detecting an end point according to the second embodiment. The processing of the method for detecting an end point illustrated in FIG. 19 is executed when the dummy wafer DW is placed on the substrate support 11 and the cleaning of the inside of the plasma processing chamber 10 is performed.

The plasma controller 102a initializes a first flag and a second flag each to 0 (S20). The first flag is a flag indicating whether the cleaning of the area near the upper electrode has been ended. The second flag is a flag indicating whether the cleaning of the area near the lower electrode has been ended. If the cleaning has not been ended, 0 is set to the first flag and the second flag, and if the cleaning has been ended, 1 is set to them.

The plasma controller 102a starts the cleaning (S21). For example, the plasma controller 102a controls the exhaust system 40 to exhaust the inside of the plasma processing chamber 10 to a certain degree of vacuum. The plasma controller 102a controls the gas supply unit 20 to introduce the cleaning gas from the gas supply unit 20 into the plasma processing space 10s. The plasma controller 102a controls the power supply 30 to supply the source RF signal and the bias RF signal in a pulse form from the first RF generation unit 31a and the second RF generation unit 31b in sync with the introduction of the cleaning gas so as to start the cleaning.

The detector 102b determines whether the value of the first flag is 1 (S22). That is, the detector 102b determines whether the cleaning of the area near the upper electrode has been ended.

If the value of the first flag is 1 (Yes at S22), the process moves to S27 described below. That is, if the cleaning of the area near the upper electrode has been ended, the process moves to S27.

On the other hand, if the value of the first flag is not 1 (No at S22), the detector 102b detects the end point of the cleaning of the area near the upper electrode from the change in any of the voltage, the current, and the phase difference between the voltage and the current measured by the measuring unit 35a in the period during which the source RF signal is On (S23).

The plasma controller 102a determines whether the end point of the cleaning of the area near the upper electrode has been detected by the detector 102b (S24). If the end point of the cleaning of the area near the upper electrode has not been detected (No at S24), the process moves to S27 described below.

On the other hand, if the end point of the cleaning of the area near the upper electrode has been detected (Yes at S24), the plasma controller 102a controls the power supply 30 to stop supply of the source RF signal from the first RF generation unit 31a (S25). The plasma controller 102a then sets 1 indicating the end of the cleaning of the area near the upper electrode to the first flag (S26).

The detector 102b determines whether the value of the second flag is 1 (S27). That is, the detector 102b determines whether the cleaning of the area near the lower electrode has been ended.

If the value of the second flag is 1 (Yes at S27), the process moves to S32 described below. That is, if the cleaning of the area near the lower electrode has been ended, the process moves to S32.

On the other hand, if the value of the second flag is not 1 (No at S27), the detector 102b detects the end point of the cleaning of the area near the lower electrode from the change in any of the voltage, the current, and the phase difference between the voltage and the current measured by the measuring unit 35b in the period during which the bias RF signal is On (S28).

The plasma controller 102a determines whether the end point of the cleaning of the area near the lower electrode has been detected by the detector 102b (S29). If the end point of the cleaning of the area near the lower electrode has not been detected (No at S29), the process moves to S32 described below.

On the other hand, if the end point of the cleaning of the area near the lower electrode has been detected (Yes at S29), the plasma controller 102a controls the power supply 30 to stop supply of the bias RF signal from the second RF generation unit 31b (S30). The plasma controller 102a then sets 1 indicating the end of the cleaning of the area near the lower electrode to the second flag (S31).

The plasma controller 102a determines whether the values of the first flag and the second flag are each 1 (S32). That is, the plasma controller 102a determines whether the cleaning of the area near the upper electrode and the area near the lower electrode has been ended. If the values of the first flag and the second flag are each not 1 (No at S32), the process moves to S22 described above. That is, if the cleaning of the area near the upper electrode and the area near the lower electrode has not been ended, the process moves to S22 to continue the cleaning.

On the other hand, if the values of the first flag and the second flag are each 1 (Yes at S32), the process is ended.

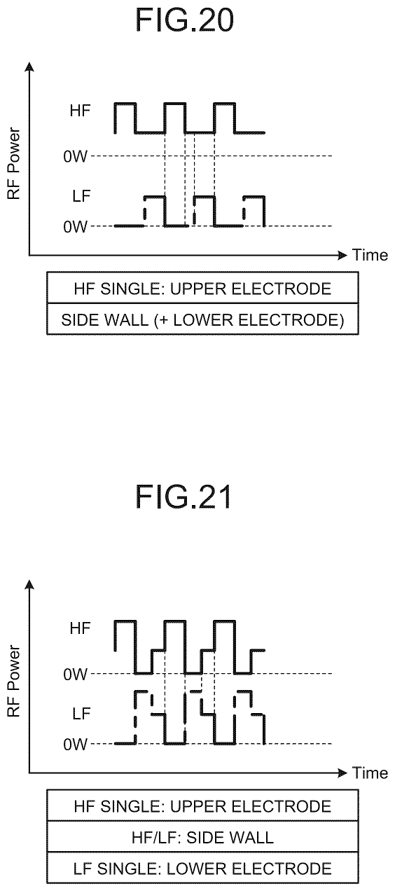

Described in the second embodiment described above as an example is, as illustrated in FIG. 15, a case in which the source RF signal and the bias RF signal are supplied from the RF power supply 31 turned on and off without their On periods overlapping. However, this is not limiting. At least either the source RF signal or the bias RF signal does not necessarily have a supply power of 0 W as being turned off. FIG. 20 is a diagram of another example of supply of the radio-frequency power according to the second embodiment. FIG. 20 illustrates periods during which the source RF signal and the bias RF signal are supplied and supply power (Power). “HF” shows a period during which the source RF signal is supplied and supply power. “LF” shows a period during which the bias RF signal is supplied and supply power. In FIG. 20, the source RF signal is supplied in a pulse form with the supply power alternately switched between two states, or high power and low power. In FIG. 20, the bias RF signal is supplied in a pulse form in the period in which the supply power of the source RF signal is the low power. In this case, the period during which the high-power source RF signal is supplied most contributes to the cleaning of the area near the upper electrode (for example, the shower head 13) inside the plasma processing chamber 10. The detector 102b can detect the end point of the cleaning of the area near the upper electrode inside the plasma processing chamber 10 from the change in any of the voltage, the current, and the phase difference between the voltage and the current measured by the measuring unit 35a in the period during which the high-power source RF signal is supplied. In the period during which the bias RF signal is supplied, the low-power source RF signal is also supplied. Upon supply of the bias RF signal and the low-power source RF signal, the plasma processing chamber 10 generates plasma near the internal side wall and the lower electrode. Thus, the period during which the bias RF signal and the low-power source RF signal are supplied most contributes to the cleaning of the area near the side wall and the lower electrode (for example, the substrate support 11) inside the plasma processing chamber 10. The detector 102b can detect the end point of the cleaning of the area near the side wall and the lower electrode inside the plasma processing chamber 10 from the change in any of the voltage, the current, and the phase difference between the voltage and the current measured by the measuring units 35a and 35b in the period during which the bias RF signal and the low-power source RF signal are supplied.

The source RF signal and the bias RF signal may be supplied with the supply power changed in stages. FIG. 21 is a diagram of another example of supply of the radio-frequency power according to the second embodiment. FIG. 21 illustrates periods during which the source RF signal and the bias RF signal are supplied and supply power (Power). “HF” shows a period during which the source RF signal is supplied and supply power. “LF” shows a period during which the bias RF signal is supplied and supply power. In FIG. 21, the source RF signal is repeatedly supplied with the supply power switched in sequence to three states, or high power, low power, and 0 W. In FIG. 21, the source RF signal is repeatedly supplied with the supply power switched in sequence to three states, or high power, low power, and 0 W, in sync with the switching of the source RF signal. In FIG. 21, the bias RF signal is set to 0 W in the period during which the source RF signal is at high power. The bias RF signal is supplied at high power in the period during which the source RF signal is 0 W. The bias RF signal is supplied at low power in the period during which the source RF signal is at low power. In this case, the period during which the high-power source RF signal is supplied most contributes to the cleaning of the area near the upper electrode (for example, the shower head 13) inside the plasma processing chamber 10. The detector 102b can detect the end point of the cleaning of the area near the upper electrode inside the plasma processing chamber 10 from the change in any of the voltage, the current, and the phase difference between the voltage and the current measured by the measuring unit 35a in the period during which the high-power source RF signal is supplied. The period during which the high-power bias RF signal is supplied most contributes to the cleaning of the area near the lower electrode (for example, the substrate support 11) inside the plasma processing chamber 10. The detector 102b can detect the end point of the cleaning of the area near the lower electrode inside the plasma processing chamber 10 from the change in any of the voltage, the current, and the phase difference between the voltage and the current measured by the measuring unit 35b in the period during which the high-power bias RF signal is supplied. In the period during which the low-power bias RF signal is supplied, the low-power source RF signal is also supplied. Upon supply of the low-power bias RF signal and the low-power source RF signal, the plasma processing chamber 10 generates plasma near the internal side wall. Thus, the period during which the low-power bias RF signal and the low-power source RF signal are supplied most contributes to the cleaning of the area near the side wall inside the plasma processing chamber 10. The detector 102b can detect the end point of the cleaning of the side wall inside the plasma processing chamber 10 from the change in any of the voltage, the current, and the phase difference between the voltage and the current measured by the measuring units 35a and 35b in the period during which the low-power bias RF signal and the low-power source RF signal are supplied.

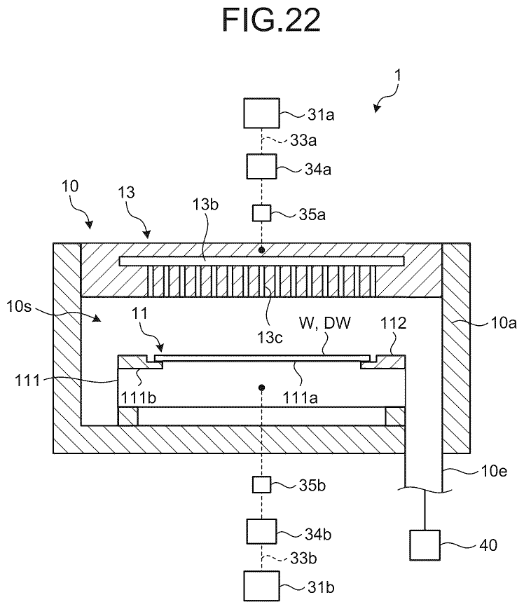

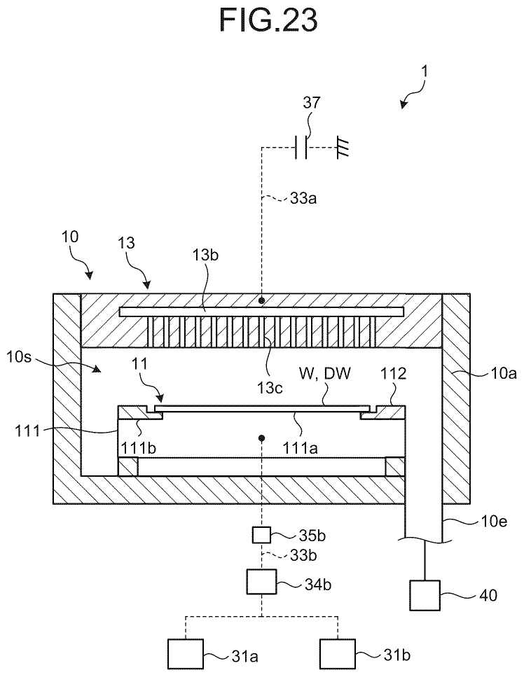

Described as an example is a case in which the plasma processing apparatus 1 supplies the source RF signal from the first RF generation unit 31a to the shower head 13 and supplies the bias RF signal from the second RF generation unit 31b to the substrate support 11. FIG. 22 is a diagram schematically illustrating an example of supply routes for the RF signals in the plasma processing apparatus 1 according to the second embodiment. FIG. 22 schematically illustrates the supply routes for the RF signals in the plasma processing apparatus 1 illustrated in FIG. 13. The first RF generation unit 31a supplies the source RF signal to the conductive member of the shower head 13 via the conductive part 33a and the impedance matching circuit 34a. The second RF generation unit 31b supplies the bias RF signal to the conductive member of the substrate support 11 via the conductive part 33b and the impedance matching circuit 34b. However, the supply routes for the RF signals are not limited to this example. For example, the source RF signal and the bias RF signal may both be supplied to the substrate support 11. FIG. 23 is a diagram schematically illustrating another example of the supply routes for the RF signals in the plasma processing apparatus 1 according to the second embodiment. The conductive part 33a is grounded via a capacitor 37. The conductive part 33b is branched to be connected to the first RF generation unit 31a and the second RF generation unit 31b. The first RF generation unit 31a supplies the source RF signal to the conductive member of the substrate support 11 via the conductive part 33b and the impedance matching circuit 34b. The second RF generation unit 31b supplies the bias RF signal to the conductive member of the substrate support 11 via the conductive part 33b and the impedance matching circuit 34b. When the source RF signal is thus supplied to the substrate support 11 also, upon supply of the source RF signal, the plasma processing chamber 10 forms a path for the source RF signal to pass near the upper electrode, and plasma is generated in the area near the internal upper part. Thus, the detector 102b can detect the end point of the cleaning of the area near the upper electrode inside the plasma processing chamber 10 from the change in any of the voltage, the current, and the phase difference between the voltage and the current measured by the measuring unit 35b in the period during which the source RF signal is supplied. The detector 102b can detect the end point of the cleaning of the area near the lower electrode inside the plasma processing chamber 10 from the change in any of the voltage, the current, and the phase difference between the voltage and the current measured by the measuring unit 35b in the period during which the bias RF signal is supplied.

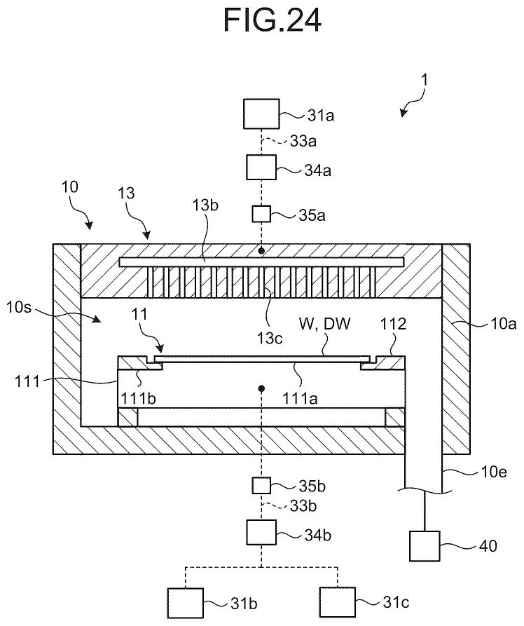

The plasma processing apparatus 1 may also supply a third RF signal to the substrate support 11 or the shower head 13. The frequency of the third RF signal is set to a frequency lower than the frequency of the source RF signal and higher than the frequency of the bias RF signal. For example, the frequency of the source RF signal is set to a frequency in a range of 40 MHz to 130 MHz. The frequency of the bias RF signal is set to a frequency lower than the frequency of the source RF signal and in a range of 400 kHz to 40 MHz. The frequency of the third RF signal is set to a frequency lower than the frequency of the source RF signal, higher than the frequency of the bias RF signal, and in a range of 13 MHz to 60 MHz. FIG. 24 is a diagram schematically illustrating another example of the supply routes for the RF signals in the plasma processing apparatus 1 according to the second embodiment. The conductive part 33b is branched to be connected to the second RF generation unit 31b and a third RF generation unit 31c. The first RF generation unit 31a supplies the source RF signal to the conductive member of the shower head 13 via the conductive part 33a and the impedance matching circuit 34a. The second RF generation unit 31b supplies the bias RF signal to the conductive member of the substrate support 11 via the conductive part 33b and the impedance matching circuit 34b. The third RF generation unit 31c supplies the third RF signal to the conductive member of the substrate support 11 via the conductive part 33b and the impedance matching circuit 34b. For example, the first RF generation unit 31a, the second RF generation unit 31b, and the third RF generation unit 31c supply the source RF signal, the bias RF signal, and the third RF signal each in a pulse form without their periods overlapping. Upon supply of the third RF signal, the plasma processing chamber 10 generates plasma near the internal side wall. Thus, the period during which the third RF signal is supplied most contributes to the cleaning of the area near the side wall inside the plasma processing chamber 10. Thus, the detector 102b can detect the end point of the cleaning of the area near the side wall inside the plasma processing chamber 10 from the change in any of the voltage, the current, and the phase difference between the voltage and the current measured by the measuring unit 35b in the period during which the third RF signal is supplied. The detector 102b can detect the end point of the cleaning of the area near the upper electrode inside the plasma processing chamber 10 from the change in any of the voltage, the current, and the phase difference between the voltage and the current measured by the measuring unit 35b in the period during which the source RF signal is supplied. The detector 102b can detect the end point of the cleaning of the area near the lower electrode inside the plasma processing chamber 10 from the change in any of the voltage, the current, and the phase difference between the voltage and the current measured by the measuring unit 35b in the period during which the bias RF signal is supplied.

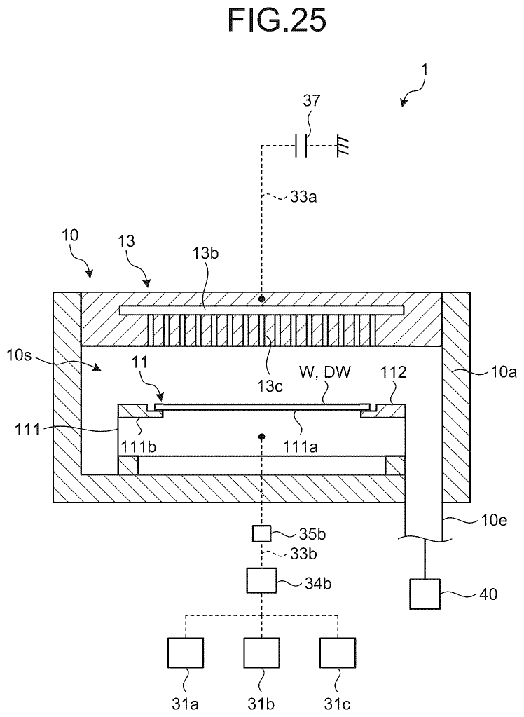

The source RF signal, the bias RF signal, and the third RF signal may be supplied to the substrate support 11. FIG. 25 is a diagram schematically illustrating another example of the supply routes for the RF signals in the plasma processing apparatus 1 according to the second embodiment. The conductive part 33a is grounded via the capacitor 37. The conductive part 33b is branched to be connected to the first RF generation unit 31a, the second RF generation unit 31b, and the third RF generation unit 31c. The first RF generation unit 31a supplies the source RF signal to the conductive member of the substrate support 11 via the conductive part 33b and the impedance matching circuit 34b. The second RF generation unit 31b supplies the bias RF signal to the conductive member of the substrate support 11 via the conductive part 33b and the impedance matching circuit 34b. The third RF generation unit 31c supplies the third RF signal to the conductive member of the substrate support 11 via the conductive part 33b and the impedance matching circuit 34b. For example, the first RF generation unit 31a, the second RF generation unit 31b, and the third RF generation unit 31c supply the source RF signal, the bias RF signal, and the third RF signal each in a pulse form without their periods overlapping. With this configuration also, the detector 102b can detect the end point of the cleaning of the area near the upper electrode inside the plasma processing chamber 10 from the change in any of the voltage, the current, and the phase difference between the voltage and the current measured by the measuring unit 35b in the period during which the source RF signal is supplied. The detector 102b can detect the end point of the cleaning of the area near the lower electrode inside the plasma processing chamber 10 from the change in any of the voltage, the current, and the phase difference between the voltage and the current measured by the measuring unit 35b in the period during which the bias RF signal is supplied. The detector 102b can detect the end point of the cleaning of the area near the side wall inside the plasma processing chamber 10 from the change in any of the voltage, the current, and the phase difference between the voltage and the current measured by the measuring unit 35b in the period during which the third RF signal is supplied.

As described above, the plasma processing apparatus 1 according to the second embodiment has the plasma processing chamber 10, the conductive member of the substrate support 11 (the electrode), the measuring units 35a and 35b, the gas supply unit 20, the RF power supply 31 (the radio-frequency power supply), and the detector 102b. The plasma processing chamber 10 is provided inside with the substrate support 11 (the placing pedestal) on which the substrate W is placed. The conductive member of the substrate support 11 is disposed inside the plasma processing chamber 10. The measuring units 35a and 35b are provided in the conductive parts 33a and 33b (wires) connected to the conductive member of the substrate support 11 or the conductive member of the substrate support 11 and measure either the voltage or the current. The gas supply unit 20 supplies the gas to be made into plasma into the plasma processing chamber 10. The RF power supply 31 supplies, to the plasma processing chamber 10, the radio-frequency power in a pulse form making the gas supplied into the plasma processing chamber 10 plasma. The detector 102b detects the end point of the plasma processing from the change in any of the voltage, the current, and the phase difference between the voltage and the current measured by the measuring units 35a and 35b with the timing synchronized with the cycle of the pulses of the radio-frequency power. With this operation, the plasma processing apparatus 1 can accurately detect the end point of the plasma processing.

The gas supply unit 20 supplies the cleaning gas as the gas to be made into plasma. The detector 102b detects the end point of the cleaning from the change in any of the voltage, the current, and the phase difference between the voltage and the current measured by the measuring unit 35 with the timing synchronized with the cycle of the pulses of the radio-frequency power. With this operation, the plasma processing apparatus 1 can accurately detect the end point of the cleaning.

The RF power supply 31 supplies, to the substrate, at least either the source RF signal (the first radio-frequency power) for generating plasma or the bias RF signal (the second radio-frequency power) for drawing the ion component in the plasma, in a pulse form. The detector 102b detects the end point of the cleaning from the change in any of the voltage, the current, and the phase difference between the voltage and the current measured by the measuring unit 35 with the timing when the combination of the source RF signal and the bias RF signal supplied most contributes to the cleaning. With this operation, the plasma processing apparatus 1 can accurately detect the end point of the cleaning.

The RF power supply 31 supplies the source RF signal to the substrate support 11 or the ceiling of the plasma processing chamber 10 (the shower head 13) and supplies the bias RF signal to the substrate support 11. The detector 102b detects the end point of the cleaning of the ceiling part inside the plasma processing chamber 10 from the change in any of the voltage, the current, and the phase difference between the voltage and the current measured by the measuring unit 35a or the measuring unit 35b in the period during which the source RF signal is supplied. The detector 102b detects the end point of the cleaning of the substrate support 11 part from the change in any of the voltage, the current, and the phase difference between the voltage and the current measured by the measuring unit 35b in the period during which the bias RF signal is supplied. With this operation, the plasma processing apparatus 1 can detect the end points of the cleaning of the ceiling part and the substrate support 11 part inside the plasma processing chamber 10 separately and accurately.

The detector 102b detects the end point of the cleaning of the side wall part inside the plasma processing chamber 10 from the change in any of the voltage, the current, and the phase difference between the voltage and the current measured by the measuring unit 35a or the measuring unit 35b in the period during which the source RF signal and the bias RF signal are supplied. With this operation, the plasma processing apparatus 1 can accurately detect the end point of the cleaning of the side wall part inside the plasma processing chamber 10.

The frequency of the source RF signal is set to a frequency in a range of 40 MHz to 130 MHz. The frequency of the bias RF signal is set to a frequency lower than the frequency of the source RF signal and in a range of 400 kHz to 40 MHz. With this configuration, the plasma processing apparatus 1 can clean the ceiling part inside the plasma processing chamber 10 by the source RF signal and clean the substrate support 11 part by the bias RF signal.

The third RF generation unit 31c supplies the third RF signal (third radio-frequency power) with a third frequency between the frequency of the source RF signal and the frequency of the bias RF signal in a pulse form. The detector 102b detects the end point of the cleaning of the side wall part inside the plasma processing chamber 10 from the change in any of the voltage, the current, and the phase difference between the voltage and the current measured by the measuring unit 35b in the period during which the third RF signal is supplied. With this operation, the plasma processing apparatus 1 can accurately detect the end point of the cleaning of the side wall part inside the plasma processing chamber 10.

The frequency of the third RF signal is set to a frequency lower than the frequency of the source RF signal, higher than the frequency of the bias RF signal, and in a range of 13 MHz to 60 MHz. With this configuration, the plasma processing apparatus 1 can clean the side wall part inside the plasma processing chamber 10 by the third RF signal.

The detector 102b determines the change amount per unit time in the voltage measured by the measuring units 35a and 35b with the timing synchronized with the cycle of the pulses of the radio-frequency power and detects the end point of the cleaning based on the timing when the change amount peaks. The detector 102b detects the timing when the certain margin time has elapsed from the timing when the change amount peaks as the end point of the cleaning. With this operation, the plasma processing apparatus 1 can accurately detect the end point of the cleaning.

The embodiments have been described above, but the embodiments disclosed here should be considered to be exemplary and not restrictive in all respects. Indeed, the embodiments described above can be embodied in a variety of forms. The embodiments described above may be omitted, replaced, or modified in various forms without departing from the scope and the gist of the claims.

For example, described in the above embodiments as an example is a case in which the plasma processing is performed on the semiconductor wafer as the substrate W, but this is not limiting. The substrate W may be any substrate.

The embodiments disclosed here should be considered to be exemplary and not restrictive in all respects. Indeed, the above embodiments can be embodied in a variety of forms. The above embodiments may be omitted, replaced, or modified in various forms without departing from the scope and the gist of the appended claims.

With respect to the above embodiments, the following addendum is further disclosed.

The present disclosure can accurately detect an end point of plasma processing.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A plasma processing apparatus comprising:
a chamber provided inside with a placing pedestal on which a substrate is placed;
an electrode disposed inside the chamber;
a measuring unit provided in the electrode or a wire connected to the electrode and configured to measure either a voltage or a current;
a gas supply unit configured to supply a gas to be made into plasma into the chamber;
a radio-frequency power supply configured to supply, to the chamber, radio-frequency power in a pulse form making the gas supplied into the chamber plasma; and
a detector configured to detect an end point of plasma processing by the plasma generated inside the chamber from a change in any of a voltage, a current, and a phase difference between the voltage and the current measured by the measuring unit with a timing synchronized with a cycle of pulses of the radio-frequency power.

2. The plasma processing apparatus according to claim 1, wherein
the gas supply unit supplies an etching gas as the gas, and
the detector detects an end point of etching from the change in any of the voltage, the current, and the phase difference between the voltage and the current measured by the measuring unit with the timing synchronized with the cycle of the pulses of the radio-frequency power.

3. The plasma processing apparatus according to claim 1, wherein
the gas supply unit supplies a cleaning gas as the gas, and
the detector detects an end point of cleaning from the change in any of the voltage, the current, and the phase difference between the voltage and the current measured by the measuring unit with the timing synchronized with the cycle of the pulses of the radio-frequency power.

4. The plasma processing apparatus according to claim 2, wherein
the radio-frequency power supply supplies at least either a first radio-frequency power with a first frequency for generating plasma or a second radio-frequency power with a second frequency lower than the first frequency for drawing an ion component in the plasma to the substrate, in a pulse form, and
the detector detects an end point of the etching from the change in any of the voltage, the current, and the phase difference between the voltage and the current measured by the measuring unit with a timing when a combination of the first radio-frequency power and the second radio-frequency power supplied most contributes to etching and a selection ratio.

5. The plasma processing apparatus according to claim 4, wherein the detector detects the end point of the etching from the change in any of the voltage, the current, and the phase difference between the voltage and the current measured by the measuring unit in a period during which the second radio-frequency power is supplied.

6. The plasma processing apparatus according to claim 4, wherein
the radio-frequency power supply supplies the first radio-frequency power and the second radio-frequency power each in a pulse form with periods during which the first radio-frequency power and the second radio-frequency power are supplied partially overlapping or without the periods during which the first radio-frequency power and the second radio-frequency power are supplied overlapping, and
the detector detects the end point of the etching from the change in any of the voltage, the current, and the phase difference between the voltage and the current measured by the measuring unit in a period during which only the second radio-frequency power is supplied.

7. The plasma processing apparatus according to claim 2, wherein
the substrate is formed with a film to be etched, and
the detector detects an end of etching of the film.

8. The plasma processing apparatus according to claim 1, wherein the radio-frequency power supply supplies the radio-frequency power in a pulse form with a frequency of 100 Hz to 10 kHz.

9. The plasma processing apparatus according to claim 1, wherein
the electrode is provided in the placing pedestal,
the wire connected to the electrode is provided with a matching circuit and is supplied with the radio-frequency power from the radio-frequency power supply, and
the measuring unit is provided closer to the electrode than the matching circuit is in the wire.

10. The plasma processing apparatus according to claim 3, wherein
the radio-frequency power supply supplies at least either a first radio-frequency power with a first frequency for generating plasma or a second radio-frequency power with a second frequency lower than the first frequency for drawing an ion component in the plasma to the placing pedestal, in a pulse form, and
the detector detects the end point of the cleaning from the change in any of the voltage, the current, and the phase difference between the voltage and the current measured by the measuring unit with a timing when a combination of the first radio-frequency power and the second radio-frequency power supplied most contributes to the cleaning.

11. The plasma processing apparatus according to claim 10, wherein
the radio-frequency power supply supplies the first radio-frequency power to the placing pedestal or a ceiling of the chamber and supplies the second radio-frequency power to the placing pedestal, and
the detector detects the end point of the cleaning of the ceiling part inside the chamber from the change in any of the voltage, the current, and the phase difference between the voltage and the current measured by the measuring unit in a period during which the first radio-frequency power is supplied and detects the end point of the cleaning of the placing pedestal part from the change in any of the voltage, the current, and the phase difference between the voltage and the current measured by the measuring unit in a period during which the second radio-frequency power is supplied.

12. The plasma processing apparatus according to claim 10, wherein the detector detects the end point of the cleaning of a side wall part inside the chamber from the change in any of the voltage, the current, and the phase difference between the voltage and the current measured by the measuring unit in a period during which the first radio-frequency power and the second radio-frequency power are supplied.

13. The plasma processing apparatus according to claim 10, wherein
the first frequency is set to a frequency in a range of 40 MHz to 130 MHz, and
the second frequency is set to a frequency lower than the first frequency and in a range of 400 kHz to 40 MHz.

14. The plasma processing apparatus according to claim 10, wherein
the radio-frequency power supply supplies a third radio-frequency power with a third frequency between the first frequency and the second frequency in a pulse form, and
the detector detects the end point of the cleaning of a side wall part inside the chamber from the change in any of the voltage, the current, and the phase difference between the voltage and the current measured by the measuring unit in a period during which the third radio-frequency power is supplied.

15. The plasma processing apparatus according to claim 14, wherein the third frequency is set to a frequency lower than the first frequency, higher than the second frequency, and in a range of 13 MHz to 60 MHz.

16. The plasma processing apparatus according to claim 3, wherein the detector determines a change amount per unit time of the voltage measured by the measuring unit with the timing synchronized with the cycle of the pulses of the radio-frequency power and detects the end point of the cleaning based on a timing when the change amount peaks.

17. The plasma processing apparatus according to claim 16, wherein the detector detects a timing when a certain margin time has elapsed from the timing when the change amount peaks as the end point of the cleaning.

18. A method for detecting an end point, the method comprising:
supplying a gas to be made into plasma into a chamber provided inside with a placing pedestal on which a substrate is placed;
supplying radio-frequency power making the gas supplied into the chamber plasma to the chamber together with the supply of the gas, in a pulse form; and
detecting an end point of plasma processing from a change in any of a voltage, a current, and a phase difference between the voltage and the current measured by a measuring unit provided in an electrode disposed inside the chamber or a wire connected to the electrode and configured to measure either a voltage or a current with a timing synchronized with a cycle of pulses of the radio-frequency power.

19. The method for detecting an end point according to claim 18, wherein
the supplying a gas supplies an etching gas as the gas, and
the detecting detects an end point of etching from the change in any of the voltage, the current, and the phase difference between the voltage and the current measured by the measuring unit.

20. The method for detecting an end point according to claim 18, wherein
the supplying a gas supplies a cleaning gas as the gas, and
the detecting detects an end point of cleaning from the change in any of the voltage, the current, and the phase difference between the voltage and the current measured by the measuring unit.
